(19) United States
(12) Patent Application Publication
(10) Pub. No.: US 2006/0016387 A1
(43) Pub. Date: Jan. 26, 2006

(54) Silicon wafer, its manufacturing method, and its manufacturing apparatus

(76) Inventors: Takashi Yokoyama, Kanagawa (JP); Koji Yoshihara, Kanagawa (JP); Toshiaki Saishoji, Kanagawa (JP); Kozo Nakamura, Kanagawa (JP); Ryota Suewa, Kanagawa (JP)

Correspondence Address: WELSH & KATZ, LTD, 120 S RIVERSIDE PLAZA, 22ND FLOOR, CHICAGO, IL, 60606, US

(21) Appl. No.: 10/534,946

(22) PCT Filed: Nov. 14, 2003
(86) PCT No.: PCT/JP03/14509

§ 371 Date: May 11, 2005

(30) Foreign Application Priority Data
Nov. 14, 2002 (JP) 2002-331288
Feb. 24, 2003 (JP) 2003-46411

(51) Int. Cl. C30B 23/00; C30B 25/00; C30B 28/12; C30B 28/14

(52) U.S. Cl. 117/84

(57) ABSTRACT

The production yield about defect free devices is improved by so controlling the size and density of void defects that they are under predetermined levels without marring the productivity. The pull-up speed V of a silicon crystal (10) by a pull-up mechanism (4) is controlled, and the rate of cooling by a cooler (30) is also controlled. As a result, the axial temperature gradient G₁ at and near the melting point of the silicon crystal (10) is increased. The growth condition V/G₁ is lowered to a temperature near the critical value under the condition that the growth rate V lies in the range from 97% to 75% of the limit rate Vmax and that the solid-liquid interface is convex with respect to the melt surface. Thus a silicon crystal (10) is grown by pulling up.

### TECHNICAL FIELD

This invention relates to a silicon wafer, its manufacturing method and its manufacturing apparatus, and more particularly relates to a manufacturing method and a manufacturing apparatus with which the size and density of void defects can be reduced, and to a silicon wafer manufactured with these method and apparatus. The present invention also relates to a method for manufacturing a silicon single crystal, and to a silicon single crystal, and more particularly relates to a method for manufacturing a defect-free silicon single crystal in which void defects, OSFs (oxidation induced stacking faults), and dislocation clusters (interstitial silicon dislocation defects) have been eliminated, and to a defect-free silicon single crystal manufactured by this method, and to an apparatus for pulling this defect-free silicon single crystal.

### BACKGROUND ART

Silicon crystals are manufactured by pulling according to the CZ (Czochralski) method. An ingot of a pulled silicon crystal is sliced into silicon wafers. A semiconductor device is produced by a device step in which a device layer is formed on the surface of a silicon wafer.

However, crystal defects called grown-in defects (defects that are introduced in the growth of the crystal) occur in the process of growing a silicon crystal.

As semiconductor circuits have become smaller and more highly integrated in recent years, it is no longer acceptable for grown-in defects to be present near the surface layer of a silicon wafer where devices are produced. The possibility of manufacturing defect-free crystals has therefore been examined.

In general, crystal defects that are included in silicon crystals and adversely affect device characteristics can be categorized into the following three types.
a) Void defects called COP (Crystal Originated Particles) and so forth, and produced by the agglomeration of vacancies.
b) OSFs (Oxidation Induced Stacking Faults).
c) Dislocation loop clusters produced by the agglomeration of interstitial silicon (interstitial silicon dislocation defects, I-defects).

Defect-free silicon single crystals are recognized or defined as crystals that include none of, or substantially none of, the above three types of defect.

The occurrence behavior of the above three types of defect is known to vary as follows with the growth conditions. This will be described through reference to FIG. 2. The horizontal axis in FIG. 2 is a growth condition V/G₁ (discussed below), and we can consider the function of the growth rate V if we fix G₁. In FIG. 2, 100A, 100B, 100C, 100D, and 100E are conceptual depictions of the size and density of various types of defect between the planar center and the edge of a silicon wafer 100 obtained from a silicon crystal 10. The planar center and the edge of the silicon wafer 100 correspond to the crystal center and the crystal edge (crystal outer periphery) of the silicon crystal 10.
i) When the growth rate V is high, as indicated by 100A and 100B in FIG. 2, the silicon crystal 10 has an excess of vacancy point defects, and only void defects occur.
ii) When the growth rate V decreases, ring-shaped OSFs (R-OSFs) occur near the outer periphery of the silicon crystal 10, resulting in a structure in which void defects are present on the inside of the R-OSF portion.
iii) When the growth rate V decreases further, there is a decrease in the radius of the ring-shaped OSFs (R-OSFs), resulting in a structure in which a region in which no defects are present is on the outside of the ring-shaped OSFs, dislocation loop clusters are produced on the outside thereof, and void defects are present on the inside of the R-OSF portion.
iv) When the growth rate V decreases even further, as indicated by 100E, the resulting structure is such that dislocation loop clusters are present in the entire silicon crystal 10.

The reason why the above-mentioned phenomena occur is believed to be that as the growth rate V decreases, the silicon crystal 10 changes from a state of excess vacancy point defects to a state of excess interstitial silicon point defects, and this change is understood to begin from the outer periphery of the silicon crystal 10.

Of the above three types of defect, the void defects of a) in particular are a cause of device isolation failure in very small devices, so there is a particular need to reduce such defects.

Void defects are produced when atomic vacancies (point defects) incorporated from a silicon melt during crystal growth agglomerate as a result of reaching a critical supersaturation during crystal cooling, and methods for detecting such defects are called LPD (laser particle defect), COP (crystal oriented particle), FPD (flow pattern defect), LSTD (laser scattering tomography defect), and so forth.

At present, as indicated by 100A and 100B in FIG. 2, the silicon crystal 10 is produced in a region in which void defects are present over the entire plane of a silicon wafer. With a silicon wafer 100 acquired from this silicon crystal 10, COPs that are materialized void defects are present on the surface. The reduction of COPs is necessary today, when a silicon wafer surface layer needs to be completely free of defects, and the device wiring width in particular has decreased to close to the COP size.

If a silicon crystal 10 in which no defects are present could be manufactured, the result would be a silicon wafer in which no COPs are present. However, extremely precise pulling control is necessary to manufacture such silicon crystals, and another drawback is poor productivity.

One way to obtain a silicon wafer that includes no COPs or other grown-in defects near the surface layer where a device circuit is produced is a method in which “a defect-free layer is grown on the wafer surface by epitaxial growth.” A problem with this method, however, is that because a step of forming a layer by epitaxial growth is introduced, the manufacturing cost is higher than with a polished wafer. A defect-free layer that includes no COPs or the like can similarly be produced as a wafer surface layer by a method involving annealing in a hydrogen or argon atmosphere, but the introduction of an annealing step again drives the cost higher than with a polished wafer.

Complete COP removal is not necessarily essential to ensuring good device quality, and if the size of these defects can be kept to a certain level or smaller, the non-defective device yield can be raised. That is, if the COP size can be made less than the device wiring width, there will be no problem in terms of isolation failure, and there will be little effect on defective devices. More specifically, although COPs of about 0.10 μm or larger as measured by particle counter are considered a problem, and must be reduced, it is known that COPs of smaller size will have little effect.

Thus, when manufacturing cost and price superiority are considered, rather than completely eliminating COPs, what is necessary is to reduce more than usual the size of those COPs that are present, and to manufacture a polished wafer with a reduced content of large COPs.

The mechanism by which void defects are formed will now be described through reference to FIGS. 1A and 1B. FIG. 1A conceptually illustrates defects in a silicon crystal 10 grown by pulling from a silicon melt 5, while FIG. 1B shows the relationship between void defect density, point defect concentration, and the temperature in the axial direction of the silicon crystal 10, corresponding to FIG. 1A. In FIG. 1B, Cv is the vacancy concentration in the silicon crystal 10, and Cv,eq is the thermal equilibrium concentration of vacancies in the silicon crystal 10. When excess vacancies are incorporated, the supersaturation of vacancies (Cv/Cv,eq) increases as temperature decreases, and void defects are formed when a critical value is reached.

As shown in FIGS. 1A and 1B, the degree of vacancy supersaturation does not reach the critical value near (up to approximately 1150° C.) the melting point of silicon (approximately 1350° C.), so point defects remain and no void defects are formed, but once the vacancy supersaturation reaches the critical value, void defects begin to occur, and the void defect density steadily increases until reaching a constant density in the void defect occurrence temperature zone (approximately 1150° C. to approximately 1080° C.).

The occurrence and growth of these void defects are greatly affected by the thermal history to which the silicon crystal is subjected during crystal growth. Parameters that are particularly important in controlling the density and size of void defects are the axial temperature gradient G₁ near the melting point, the axial temperature gradient G₂ in the void defect occurrence temperature zone, and the growth rate V of the silicon crystal 10.

The size and density of void defects are known to be affected by the growth conditions V/G₁ and V·G₂ expressing thermal history during crystal pulling. Of these, the growth condition V/G₁ affects the amount of vacancies that make up void defect, and determines the vacancy concentration initially introduced. The growth condition V·G₂ is the crystal cooling rate in the void defect occurrence temperature zone, and affects the growth of void defects.

The relationship between the growth condition V/G₁ (V·G₂), the point defect (vacancy) concentration, and the defect type is expressed as the conceptual diagram shown in the above-mentioned FIG. 2.

At present, as indicated by 100A and 100B in FIG. 2, the density and size of void defects are controlled by varying the cooling rate V·G₂ in the void defect occurrence temperature zone in the high V/G₁ region of relatively stable vacancy concentration in which the OSF region is moved to the crystal outer periphery (normal conditions).

As shown in FIG. 3, the density and size of void defects are in a roughly inversely proportional relationship. The greater is the cooling rate V·G₂, the smaller is the defect size, and the lower is the cooling rate V·G₂, the larger is the defect density. In the high V/G₁ region, the total concentration of vacancies constituting void defects is substantially constant, and as shown by 100A and 100B, the density and size of defects is determined just by the cooling rate V·G₂, and are almost unaffected by V/G₁.

However, in the region close to the critical value at which V/G₁ changes from a void defect region into an OSF region, as shown by 100C and 100D, the closer V/G₁ is to the critical value and the lower is the total vacancy concentration, the more pronounced is the reduction in defect size by the effect of V/G₁ (low V/G₁ effect). Specifically, the smaller is V/G₁ and the larger is cooling rate V·G₂ in the region where V/G₁ is close to the critical value, the smaller is the size of the void defects. This mechanism will now be described.

Void defects are formed after the degree of supersaturation of vacancies exceeds a critical value. When the total vacancy concentration is low, as indicated by the one-dot chain line in FIG. 1B, the temperature decreases when the vacancy supersaturation C′v/Cv,eq exceeds a critical value (the critical supersaturation). Therefore, the void defect formation temperature decreases and the void defect growth rate (vacancy agglomeration rate) also decreases, so the size of the voids does not become large. Also, the elimination of the vacancy supersaturation slows and new void nuclei are generated, and as a result, the void defect density increases, but the void defects to not become large in size.

If we take into account ensuring the performance of a silicon wafer, a state of small void defect size must be created uniformly in the radial direction (from planar center to the edge) of the silicon wafer 100. The silicon crystal 10 loses heat from its surface, so the radial distribution of the axial temperature gradient G₁ near the melting point is small at the crystal center, and gradually increases toward the silicon crystal outer periphery. Therefore, if G₁ has a large distribution differential, if the growth rate V is merely lowered in order to achieve a low V/G₁, there is the danger that V/G₁ will be relatively low around the periphery of the silicon wafer 100, R-OSFs will occur at the periphery, or the void defect size and void defect density will be non-uniform in the wafer plane, leading to partial increases in defect size and density.

Prior art disclosed in patent documents will now be described.

[Prior Art 1]

Patent Document 1 (Japanese Patent Application Laid-Open No. 2001-278692) discusses an invention in which the number of large COPs is reduced by controlling the growth conditions V/G₁ and V·G₂ (defined as the time passing through the void defect occurrence temperature zone) at the silicon crystal center. In Patent Document 1, however, the temperature gradient G₁ is restricted at the crystal center, and the radial distribution of the temperature gradient G₁ is not taken into account at all. Accordingly, as mentioned above, there is the danger that R-OSFs will occur around the wafer periphery, or that partial increases in defect size and density will occur in the wafer plane. Also, Patent Document 1 discusses a technique whereby the temperature gradient G₁ is increases by providing a cooling cylinder for cooling the silicon crystal during its growth.

[Prior Art 2]

Patent Document 2 (Japanese Patent Application Laid-Open No. 2000-313695) discusses an invention in which the number of COPs is reduced by setting the radial distribution (ΔV/G₁) of the V/G₁ to 10% or less. However, as discussed below, the growth rate V cannot be raised over a specific level merely by controlling the radial distribution (ΔV/G₁) of the V/G₁ as a parameter. Because there is a limit to the pulling rate, there is the danger that productivity will suffer.

[Prior Art 3]

Patent Document 3 (Japanese Patent Application Laid-Open No. 2001-261495), submitted by the present applicant, discusses that the critical value and the V/G₁ radial distribution vary with the shape of the solid-liquid interface, which is the boundary between the silicon melt and the silicon crystal 10.

The above Prior Art 1 and 2 do not take the shape of the solid-liquid interface into account whatsoever. Specifically, in Prior Art 1 and 2, the defect size and density cannot be precisely controlled unless the change in the critical value and the V/G₁ radial distribution are ascertained by taking into account the shape of the solid-liquid interface.

The present invention was conceived in light of the above situation, and the first problem it attempts to solve is to increase the yield of non-defective devices by being able to precisely control the size and density of void defects to be at or below a certain level, without adversely affecting productivity.

In order to obtain a silicon wafer that includes no grown-in defects near the surface layer where a device circuit is produced, a method in which “a defect-free single crystal ingot is manufactured by controlling the crystal growth conditions” has been attempted in the past, and was known from the patent publication given below.

[Prior Art 4]

Patent Document 4 (Japanese Patent Application Laid-Open No. 8-3303161) discloses the method of 1) above, in which “a defect-free single crystal ingot is manufactured by controlling the crystal growth conditions.” Specifically, the invention discussed here involves manufacturing a crystal that includes no defects by controlling the growth condition V/G (V: growth rate, G: axial temperature gradient of the crystal) such that there will be no excess of vacancies or interstitial silicon in the crystal.

Specifically, Patent Document 4 states that a defect-free region (one including none of the three types of defect) is present between the R-OSF portion and the dislocation loop cluster generation region. The defect-free region corresponds to a region of transition from a vacancy excess state to an interstitial silicon excess state, and corresponds to a neutral state that has not yet reached an excess amount at which any defects can be generated. In view of this, if we let V (mm/min) be the crystal pulling rate, and G (° C./mm) be the average temperature distribution within the crystal in the axial direction between the melting point of silicon and 1300° C., then if the crystal is pulled while controlling the ratio V/G to be from 0.20 to 0.22 mm²/° C.min, the above-mentioned neutral state can be realized in the entire crystal.

If we assume here that G will be uniform in the radial direction if the above conditions are met, then when G=3.0° C./mm, for example, the pulling rate V may be controlled to 0.63±0.03 mm/min. Accomplishing this control is not impossible in an industrial setting.

Nevertheless, this only refers in principle to the maximum allowable range of the pulling rate V. The reason for this is that G is usually not consistent in the radial direction. If we assume that G varies, the allowable range of the pulling rate V is reduced markedly, and when the change in G in the radial direction reaches 10%, the allowable range for the pulling rate V drops to zero. This means that no change in the pulling rate V is allowed even with a very slight drop in the uniformity of G, making it extremely difficult to keep the growth condition V/G within the above range. Also, V/G varies dynamically during crystal growth. This makes it difficult to keep the growth condition V/G within the allowable range, defect-free crystals are acquired at a low proportion, and the cost of manufacturing the crystal ends up being high. Therefore, in practical terms it is impossible to manufacture a defect-free crystal stably in an industrial setting.

[Prior Art 5]

In Patent Document 5 (Japanese Patent Application Laid-Open No. 11-199387) is proposed a method for manufacturing an interstitial silicon-dominant defect-free crystal, which focuses on the fact that the above-mentioned neutral defect-free region includes two types: a vacancy-dominant defect-free region and an interstitial silicon-dominant defect-free region. In Patent Document 2, it is stated that a defect-free crystal can be pulled up if the growth condition is such that the change in G in the radial direction of the crystal is within a range of (Gmax−Gmin)/Gmin<20%, where Gmax is the maximum value and Gmin is the minimum value, but in practical terms this growth condition also has a narrow allowable range, and the industrial manufacture of a defect-free crystal is believed to be substantially impossible, just described above as in Prior Art 4.

[Prior Art 6]

In Patent Document 6 (Japanese Patent Application Laid-Open No. 11-79889), it is proposed that in order to achieve the above-mentioned neutral defect-free region throughout the crystal, the crystal be pulled such that the shape of the solid-liquid interface is in a smooth state, that is, such that the height of every part of the solid-liquid interface falls within ±5 mm of the average height. It is stated that applying a magnetic field to the melt is an effective way to obtain a solid-liquid interface with a smooth shape, and that it is particularly favorable to use a horizontal magnetic field of at least 2000 gauss. It is stated that thus keeping the shape of the solid-liquid interface smooth results in a uniform G, and that if we let Gedge be the G at the edge of the crystal and Gcenter be the G at the center of the crystal, G stays within a consistently uniform range in which Gedge−Gcenter<0.5° C./mm, and a defect-free crystal is obtained.

However, smoothing the solid-liquid interface does not mean that G will immediately become uniform, and the industrial manufacture of a defect-free crystal by keeping the solid-liquid interface smooth is believed to be impossible.

[Prior Art 7]

In Patent Document 7 (Japanese Patent Application Laid-Open No. 2000-159594) it is proposed that in order to achieve the above-mentioned neutral defect-free region throughout the crystal, the crystal be pulled such that V/G is from 0.16 to 0.18 mm²/° C.min, and Gedge/Gcenter<1.10.

However, in practical terms this growth condition also has a narrow allowable range, and it is likely that a defect-free crystal will be acquired at a low rate and the cost will be high.

[Prior Art 8]

In Patent Document 3, submitted by the present inventors, it is proposed that a defect-free crystal be manufactured by adjusting two indices: the axial temperature gradient of the crystal outer periphery near the solid-liquid interface, and the difference between the height of the solid-liquid interface at the crystal center and the height around the periphery of the crystal. With the technique in Patent Document 3, it was possible to use the above-mentioned two indices to uniformly organize the growing conditions for a defect-free crystal that have been indicated by various indices in the past, and to find the growth condition with which a defect-free crystal can be grown most easily.

It has been found, however, that the allowable range of the growth condition V/G is still narrow even under optimal growing conditions. It is not impossible to keep the growth condition V/G within this narrow allowable range, but inevitably the defect-free crystal will be acquired at a low rate and the cost will be high.

With the above Prior Art 4 to 8, in every case the ratio V/G between the growth rate V and the axial temperature gradient G near the solid-liquid interface is controlled to within an extremely narrow allowable range, and this, coupled with the fact that V/G varies dynamically during crystal growth, makes control very difficult, results in a low defect-free crystal acquisition rate, and drives up the crystal manufacturing cost, so the stable industrial manufacture of defect-free silicon single crystals was substantially impossible.

Meanwhile, a problem indicated in the past was that carbon was admixed into the melt, increasing the carbon concentration in the pulled silicon single crystal, in the process of melting a polycrystalline silicon raw material. When carbon reaches a high concentration in a silicon single crystal, it adversely affects the electrical characteristics of a semiconductor device manufactured from this crystal, and also becomes a source of crystal defects.

The following are believed to be the two main causes of carbon being contained in a silicon single crystal grown by CZ method.
1) As shown in FIG. 25, CO gas 112 is produced by a reaction between a quartz crucible 103a and a graphite crucible 103b that covers and supports the crucible 103a, this CO gas 112 comes into contact with a silicon melt 105, and this supplies carbon to the melt 105.
2) CO gas 112 is produced by a reaction between the trace amount of oxygen in the atmosphere and graphite members such as a heater 109 inside a CZ furnace 102, this CO gas 112 comes into contact with a silicon melt 105, and this supplies carbon to the melt 105.

Many graphite members, such as the heater 109, are used inside the CZ furnace 102, and these graphite members are exposed to high temperatures. Consequently, the generation of the CO gas 112 inside the CZ furnace 102 is inevitable. As a result, a certain amount of carbon ends up being contained in the silicon single crystal that is pulled up. It is known that the density of oxygen precipitate produced when a silicon wafer is heat treated increases proportionally to the carbon concentration. This carbon concentration-dependent effect becomes pronounced when the carbon concentration goes over 1×10¹⁶ atoms/cm³, and a method in which the carbon concentration in a silicon single crystal is controlled to not more than 1×10¹⁶ atoms/cm³ has been proposed in the past. Also, since more precise control of oxygen precipitation has become necessary in recent years, techniques for further lowering the carbon concentration have been proposed.

The following is prior art related to reducing the carbon concentration in a silicon single crystal.

[Prior Art 9]

Patent Document 8 (Japanese Patent Application Laid-Open No. 53-45679) discusses a technique for lowering the carbon concentration in a silicon single crystal by preventing the generation of the CO gas 112 by covering the crucible 103b, the heater 109, a shield (heat shield 108), and other such members composed of graphite with SiC (silicon carbide).

[Prior Art 10]

Patent Documents 9, 10, 11, 12, and 13 (Japanese Patent Application Laid-Open Nos. 54-119375, 56-21758, 63-319288, 2-172884, and 6-16490) discuss a technique for providing a purge tube inside the CZ furnace 102 so as to increase the flow of argon gas 107, and thereby efficiently exhaust the CO gas 112 to outside the CZ furnace 102 without directing the CO gas 112 toward the melt 105.

Specifically, by providing a purge tube inside the CZ furnace 102, the CO gas 112 generated from the crucible 103b, the heater 109, and other members composed of graphite can be effectively prevented by the flow of purge gas from coming into contact with the silicon melt 105 side, which lowers the carbon concentration in the silicon single crystal.

[Prior Art 11]

Patent Document 14 (Japanese Patent Application Laid-Open No. 6-56572) discusses a technique in which a “crucible top barrier means” is provided inside the CZ furnace 102, and the atmosphere inside the furnace is isolated from the atmosphere inside the crucible 103a holding the raw material in the course of melting the raw material silicon, in which the graphite members reach their highest temperature and there is pronounced generation of the CO gas 112, thereby lowering the carbon concentration in the silicon single crystal.

[Prior Art 12]

Patent Documents 15 and 16 (Japanese Patent Application Laid-Open Nos. 5-319976, 7-89789) discuss a technique in which the graphite members inside the CZ furnace 102 are covered with SiC, TiC, NbC, TaC, ZrC, or BN, a dedicated passage and exhaust port for exhausting the CO gas 112 are provided, these control the flow of purge gas, the CO gas 112 generated from the crucible 103b, the heater 109, and other members composed of graphite is prevented from coming into contact with the silicon melt 105 side, and the carbon concentration in the silicon single crystal is thereby lowered. It is also stated that this apparatus constitution lowers the carbon concentration to 1×10¹⁴ atoms/cm³.

However, with the above Prior Art 9 to 12, in every case the CZ furnace members must be covered, or a purge tube, passage, exhaust port, or “crucible top barrier means” must be provided, which increases the number of manufacturing steps in the manufacture of the CZ furnace and also increases the number of parts, which leads to higher cost.

[Prior Art 13]

Non-Patent Document 1 (A. J. R. de Kock and W. M. van de Wijgert, Journal of Crystal Growth, Vol. 49 (1980), 718) states that the occurrence of defects related to interstitial silicon (called B defects) is promoted the higher is the carbon concentration in the silicon single crystal.

However, what substance of B defects are and the relationship between B defects and dislocation clusters (sometimes called A defects) are still not clear even now. Further, no mention is made of the relationship between carbon concentration and dislocation clusters.

In view of this, the present invention was conceived in an attempt to solve the problems encountered with the above Prior Art 4 to 8, and the second problem it attempts to solve is to expand the allowable range for the growth condition V/G with which defect-free crystals can be obtained, so that the growth condition V/G can be easily controlled even though V/G varies dynamically during crystal growth, and to increase the defect-free crystal acquisition rate, lower the cost of manufacturing crystals, and make it possible to easily and stably manufacture defect-free silicon single crystals industrially.

In addition to solving the above-mentioned second problem, the present invention was also conceived in an attempt to solve the problems encountered with the above Prior Art 9 to 12, and the third problem it attempts to solve is to utilize existing CZ furnace members effectively, without having to provide new members or to cover the members, and thereby lower the carbon concentration and reduce the cost of manufacturing a pulling apparatus.

### DISCLOSURE OF THE INVENTION

The first invention is a method for manufacturing a silicon wafer, in which a silicon crystal is pulled from a silicon melt, and a silicon wafer is acquired from the pulled silicon crystal,
wherein the silicon crystal is pulled up by lowering a growth condition V/G₁ (V: growth rate, G₁: axial temperature gradient near a melting point of the silicon crystal) to near a critical value in a state in which the axial temperature gradient G₁ near the melting point of the silicon crystal is increased and a solid-liquid interface, which is a boundary between the silicon crystal and the melt during the pulling of the silicon crystal, is convex with respect to the melt surface.

The second invention is the first invention, wherein a cooler is used to cool the silicon crystal, thereby lowering the growth condition V/G₁ to near the critical value in a state in which the solid-liquid interface is convex with respect to the melt surface within a range in which the growth rate V is from 75 to 97% of Vmax (the limit growth rate at which growth is possible without deformation of the silicon crystal), and the silicon crystal is pulled in which no OSF (oxidation induced stacking fault) region is present anywhere in the plane of the silicon wafer.

The third invention is the first invention, wherein a cooler is used to cool the silicon crystal, thereby lowering the growth condition V/G₁ to near the critical value in the state in which the axial temperature gradient G₁ near the melting point of the silicon crystal has been increased.

The fourth invention is the first invention, wherein a magnetic field is applied to the silicon melt to make the solid-liquid interface convex with respect to the melt surface.

The fifth invention is the first invention, wherein a cooler is used to cool the silicon crystal, and a rotational speed of the silicon crystal, or a rotational speed of the crucible containing the silicon melt, is adjusted, thereby making the solid-liquid interface convex with respect to the melt surface.

The sixth invention is a method for manufacturing a silicon wafer, in which a silicon crystal is pulled from a silicon melt, and a silicon wafer is acquired from the pulled silicon crystal,
wherein a cooler is used to cool the silicon crystal, thereby lowering a growth condition V/G₁ to near a critical value in a state in which the axial temperature gradient G₁ near a melting point of the silicon crystal has been increased, and
the silicon crystal is pulled in which no OSF (oxidation induced stacking fault) region is present in a plane of the silicon wafer at least from a center of the plane up to 10 mm from an outer periphery.

The seventh invention is the sixth invention, wherein an oxygen concentration in the silicon crystal is controlled to be not more than 12.5×10¹⁷ atoms/cm³ (Year 1979 ASTM).

The eighth invention is the sixth invention, wherein the silicon wafer is subjected to heat treatment at 1000° C. or higher so that OSF nuclei will not materialize as OSFs in the silicon wafer.

The ninth invention is the sixth invention, wherein the silicon wafer is subjected to heat treatment at 1000° C. or higher in a non-oxidative atmosphere so that OSF nuclei will not materialize as OSFs in the silicon wafer and so that void defects will be eliminated in the silicon wafer surface layer.

The tenth invention is an apparatus for manufacturing a silicon wafer, with which a silicon crystal is pulled from a silicon melt by a pulling mechanism, and the silicon wafer is acquired from the pulled silicon crystal,
wherein a cooler for cooling the silicon crystal is provided above the silicon melt, and
a silicon crystal pulling rate by the pulling mechanism and an amount of cooling by the cooler are adjusted,
thereby lowering a growth condition V/G₁ (V: growth rate, G₁: axial temperature gradient near a melting point of the silicon crystal) to near a critical value in a state in which the axial temperature gradient G₁ near the melting point of the silicon crystal is increased and a solid-liquid interface, which is a boundary between the silicon crystal and the melt during the pulling of the silicon crystal, is convex with respect to a melt surface,
and the silicon crystal is pulled up.

The eleventh invention is the tenth invention, wherein the cooler is used to cool the silicon crystal, thereby lowering the growth condition V/G₁ to near the critical value in the state in which the solid-liquid interface is convex with respect to the melt surface within a range in which the growth rate V is from 75 to 97% of Vmax (a limit growth rate at which growth is possible without deformation of the silicon crystal),
and the silicon crystal is pulled in which no OSF (oxidation induced stacking fault) region is present anywhere in a plane of the silicon wafer.

The twelfth invention is an apparatus for manufacturing a silicon wafer, in which a silicon crystal is pulled from a silicon melt, and the silicon wafer is acquired from the pulled silicon crystal,
wherein a cooler for cooling the silicon crystal is provided above the silicon melt, and
a silicon crystal pulling rate by the pulling mechanism and an amount of cooling by the cooler are adjusted,
thereby lowering a growth condition V/G₁ to near a critical value in a state in which an axial temperature gradient G₁ near a melting point of the silicon crystal has been increased, and
the silicon crystal is pulled in which no OSF (oxidation induced stacking fault) region is present in a plane of the silicon wafer at least from a center of the plane up to 10 mm from an outer periphery.

The thirteenth and fourteenth inventions are the tenth or twelfth invention, wherein the cooler is disposed so as to surround the silicon crystal at a distance of 30 to 500 mm from the silicon melt.

The fifteenth and sixteenth inventions are the tenth or twelfth invention, wherein a heat shield is provided above the silicon melt, and a gap between a lower end of the heat shield and the silicon melt surface is set to between 20 and 100 mm.

The seventeenth invention is a silicon wafer, acquired by pulling from a silicon melt,
wherein no OSF (oxidation induced stacking fault) region is present anywhere in a plane of the silicon wafer, an average void defect density over the entire plane of the silicon wafer is not more than 5×10⁶/cm³, and an average void defect size over the entire plane of the silicon wafer is not more than 100 nm.

The eighteenth invention is a silicon wafer, acquired by pulling from a silicon melt,
wherein no OSF (oxidation induced stacking fault) region is present in a plane of the silicon wafer at least from a center of the plane up to 10 mm from an outer periphery, an average void defect density in the plane of the silicon wafer at least from a center of the plane up to 10 mm from an outer periphery is not more than 5×10⁶/cm³, and an average void defect size is not more than 100 nm.

The first, second, third, fourth, fifth, tenth, eleventh, thirteenth, fourteenth, fifteenth, and sixteenth inventions involve the manufacture of a silicon wafer in which no OSF region is present in the plane of the wafer.

With the present invention, the pulling rate V of the silicon crystal 10 by a pulling mechanism 4 is adjusted, and the amount of cooling by a cooler 30 is adjusted, so that the growth condition V/G₁ is lowered to near the critical value in a state in which the axial temperature gradient G₁ near the melting point of the silicon crystal 10 is increased and the solid-liquid interface is convex with respect to the melt surface within a range in which the growth rate V is from 75 to 97% of Vmax (the limit growth rate at which growth is possible without deformation of the silicon crystal), and the silicon crystal 10 is pulled up. In addition to adjusting the amount of cooling by the cooler 30, the silicon crystal rotational speed S/R and the crucible rotational speed C/R are adjusted as needed so that the solid-liquid interface will be convex with respect to the melt surface. The solid-liquid interface may be made convex with respect to the melt surface by applying a magnetic field to the silicon melt instead of adjusting the amount of cooling by the cooler 30.

Cooling the silicon crystal 10 with the cooler 30 increases G₁ and allows the rate V to be kept high (at least 75% of Vmax) when V/G₁ has been lowered to near the critical value (FIG. 10). FIG. 10 shows the relationship between the solid-liquid interface shape and the growth rate of a silicon crystal 10 with a diameter of 200 mm. In FIG. 10, Vmax corresponds to 1.48 mm/min, and the value of V at 75% of Vmax corresponds to 1.11 mm/min. In order to obtain an effect of shrinking the void defect size, it is preferable for the pulling rate V to be lowered to near the lower limit rate at which no OSF occurs (75% of Vmax) (FIG. 12). Even though the rate is lowered here, the rate is still sufficiently high compared to the lower limit pulling rate at which no OSF occurs under ordinary conditions with no cooler 30 (0.76 mm/min; FIG. 8), and there is no drop in productivity.

With the present invention, the growth rate V/G₁ is lowered to near the critical value in a state in which the solid-liquid interface is convex with respect to the melt surface, so just as in FIG. 7C, the radial distribution of V/G₁ in the wafer plane will be uniform at or above a certain level, OSFs can be prevented from occurring in the wafer plane, and the lower V/G₁ has the effect of reducing the size and density of void defects. Furthermore, since the rate V can be kept higher than under ordinary conditions, V·G₂ is larger, and the high V·G₂ effect allows the defect size to be further decreased (see FIG. 3). Therefore, the silicon wafer indicated by 100D in FIG. 2 is obtained, and the void defect size and density over the entire plane of the silicon wafer 100D can be reduced to the level indicated by the hatched area in FIG. 5. The fact that the lateral width of the silicon wafer 100D shown in FIG. 2 is narrower than the lateral width of the silicon wafers 100A and 100B obtained under ordinary conditions indicates that V/G₁ has become uniform within the wafer plane, and the void defect size and density have been uniformly decreased within the wafer plane.

Furthermore, with the present invention, since the cooler 30 is used to make the solid-liquid interface convex, the apparatus cost can be kept lower than when the same thing is accomplished by application of a horizontal magnetic field.

The sixth, seventh, eighth, ninth, twelfth, thirteenth, fourteenth, fifteenth, and sixteenth inventions involve the manufacture of a silicon wafer in which no OSFs are present in the silicon wafer plane at least from the center of the plane up to 10 mm from the outer periphery.

With the present invention, the pulling rate V of the silicon crystal 10 by the pulling mechanism 4 is adjusted, and the amount of cooling by the cooler 30 is adjusted, so that the growth condition V/G₁ is lowered to near the critical value in a state in which the axial temperature gradient G₁ near the melting point of the silicon crystal is increased, and the silicon crystal 10 is pulled up.

With the present invention, cooling the silicon crystal 10 with the cooler 30 increases G₁ and allows the rate V to be kept higher when V/G₁ has been lowered to near the critical value. However, since the occurrence of an OSF region is allowable around the outer periphery of the silicon crystal 10, the solid-liquid interface is made slightly convex downward, as shown in FIG. 10, and the pulling rate V is only about 70% of Vmax, and is lower than when the presence of an OSF region is not allowed, as shown in FIG. 12. Therefore, a further decrease in the pulling rate V enhances even more the shrinking of the void defect size. Even though the rate is lowered here, the rate is still on about the same level as the lower limit pulling rate at which no OSF occurs under ordinary conditions with no cooler 30 (0.76 mm/min; FIG. 8), and there is no drop in productivity.

With the present invention, since V/G₁ is lowered to near the critical value, a low V/G₁ effect is obtained and the void defect size and density can be reduced. Furthermore, since the rate V is kept high (the same level as under ordinary conditions), V·G₂ is larger, and the effect of a higher V·G₂ is that the defect size can be further decreased (see FIG. 3). Therefore, the silicon wafer indicated by 100C in FIG. 2 is obtained, and the void defect size and density in the plane of the silicon wafer 100C at least from the center of the plane up to 10 mm from the outer periphery can be reduced to the level indicated by the hatched area in FIG. 5.

The fact that the lateral width of the silicon wafer 100C shown in FIG. 2 is narrower than the lateral width of the silicon wafers 100A and 100B obtained under ordinary conditions indicates that V/G₁ has become uniform within the wafer plane, and the void defect size and density have been uniformly decreased within the wafer plane.

The seventeenth invention is a silicon wafer manufactured with the manufacturing method or apparatus of the first, second, third, fourth, fifth, tenth, eleventh, thirteenth, fourteenth, fifteenth, and sixteenth inventions. The silicon wafer 100D of the present invention is manufactured such that no OSF region is present anywhere in the plane of the silicon wafer, from the center of the plane to the edge. The region indicated by the hatching in FIG. 5 indicates the range of the average void defect density and the average void defect size in the entire plane of the silicon wafer 100D of the present invention. The silicon wafer 100D of the present invention has an average void defect density in the entire wafer plane of 5×10⁶/cm³ or less, and has an average void defect size of 100 nm or less.

The eighteenth invention is a silicon wafer manufactured with the manufacturing method or apparatus of the sixth, seventh, eighth, ninth, twelfth, thirteenth, fourteenth, fifteenth, and sixteenth inventions. The silicon wafer 100C of the present invention is manufactured such that no OSF region is present in the plane of the silicon wafer at least from the center of the plane up to 10 mm of the outer periphery. The region indicated by the hatching in FIG. 5 indicates the range of the average void defect density and the average void defect size in the region to the inside of R-OSF of the silicon wafer 100C of the present invention. The silicon wafer 100C of the present invention has an average void defect density in the entire wafer plane of 5×10⁶/cm³ or less and an average void defect size of 100 nm or less in the region to the inside of R-OSF.

The nineteenth invention is a method for manufacturing a defect-free silicon single crystal in which void defects, OSFs (oxidation induced stacking faults), and dislocation clusters (interstitial silicon dislocation defects) have been eliminated by setting a carbon concentration to 3×10¹⁵ atoms/cm³ or less and adjusting a growth condition V/G₁ (V: growth rate, G₁: axial temperature gradient of the crystal).

The twentieth invention is a defect-free silicon single crystal in which void defects, OSFs (oxidation induced stacking faults), and dislocation clusters (interstitial silicon dislocation defects) have been eliminated, manufactured by setting a carbon concentration to 3×10¹⁵ atoms/cm³ or less and adjusting a growth condition V/G (V: growth rate, G: axial temperature gradient of the crystal).

The twenty-first invention is an apparatus for pulling a silicon single crystal, comprising: a single crystal pulling chamber in which a carrier gas is supplied from above and exhausted from below; a crucible that is provided inside the single crystal pulling chamber, and into which a raw material is supplied and melted; and a heat shield that is disposed above the crucible, for guiding the carrier gas to a melt surface inside the crucible, in which the silicon single crystal is pulled from the melt inside the crucible,
wherein the heat shield can be raised and lowered,
the heat shield is positioned where a carbon concentration inside the pulled silicon single crystal is 3×10¹⁵ atoms/cm³ or less, and
the silicon single crystal is pulled while a growth condition V/G (V: growth rate, G: axial temperature gradient of the crystal) is adjusted such that void defects, OSFs (oxidation induced stacking faults), and dislocation clusters (interstitial silicon dislocation defects) are eliminated from the pulled silicon single crystal.

The teaching of the present invention lies in the discovery that the occurrence of dislocation clusters is suppressed by lowering the carbon concentration in a silicon single crystal to below the conventional level, and the discovery that when [the carbon concentration] is reduced to a certain level, there is a sharp decrease in the occurrence of dislocation clusters, and the allowable range for the growth condition V/G under which defect-free crystals can be obtained is sharply expanded.

Let us consider how this relates to the above-mentioned Prior Art 13. Prior Art 13 only suggests that the occurrence of B defects is dependent on the carbon concentration, but the teaching of the present invention lies in the discovery that a B defect is a precursor to the occurrence of a dislocation cluster, and that lowering the carbon concentration suppresses the occurrence of B defects, which in turn suppresses the occurrence of dislocation clusters, which expands the allowable range of the growth condition V/G under which a defect-free crystal can be obtained.

The present invention is illustrated in FIG. 21. The horizontal axis in FIG. 21 is the carbon concentration in a silicon single crystal (atoms/cm³), while the vertical axis is the growth condition V/G standardized at a critical value (V/G)₀ of V/G in a carbon-free crystal.

It can be seen from FIG. 21 that when the carbon concentration in a silicon single crystal is not higher than 3×10¹⁵ atoms/cm³, there is a sharp expansion of the range over which defect-free crystals can be manufactured (defect-free region). This means that there is a larger allowable range for the V/G under which defect-free crystals can be obtained on the vertical axis, and even though V/G varies dynamically during crystal growth, the growth condition V/G is easy to control, defect-free crystals are acquired at a higher rate, and the cost of manufacturing crystals decreases. As a result, it is possible for defect-free silicon single crystals to be manufactured easily and stably in an industrial setting. The means and method for lowering the carbon concentration in the silicon single crystal may be the above-mentioned Prior Art 9 to 12, or the technique disclosed in this Specification may be employed.

In particular, with the twenty-first invention, a reduction in the carbon concentration is achieved by utilizing an existing heat shield 108 in the CZ furnace 102, as shown in FIG. 28.

Specifically, the heat shield 108 is located at position A where its upper end touches the inner walls of the CZ furnace 102.

When the heat shield 108 is positioned at position A, argon gas 107 flows along with the CO gas 112 from the outside of the heat shield 108 toward the melt 105 via the upper end and the inside of the heat shield 108. That is, no flow is formed that rotate up and down around the heat shield 108. Specifically, the flow of the argon gas 107 is straightened, picks up the CO gas 112 generated inside the CZ furnace 102, goes under the heat shield 108 from above the CZ furnace 102, through the heater 109 and the graphite crucible 103b, and is exhausted efficiently from beneath the CZ furnace 102. This straightening of the flow of the argon gas 107 causes not only the CO gas 112 that drifts to the top of the CZ furnace 102, but also the CO gas 112 generated by a reaction between the quartz crucible 103a and the graphite crucible 103b, to be efficiently exhausted downward, so the amount of carbon incorporated into the melt 105 during melting is markedly reduced compared to the case in FIG. 29. This affords a reduction in the carbon concentration of a pulled silicon single crystal to 3×10¹⁵ atoms/cm³ or less.

Further, since the argon gas 107 is efficiently exhausted as a result of the flow straightening of the gas, impurities such as amorphous silicon in the CZ furnace 102 are also efficiently exhausted, which provides the side benefit that furnace contamination can be reduced over that in the past.

Also, since the heat shield 108 is located at position A where it touches the inner walls of the CZ furnace 102, swaying of the heat shield 108 as a result of gas flow is suppressed, and a more stable gas flow is formed.

In the pulling step, the silicon single crystal is pulled while the growth condition V/G (V: growth rate, G: axial temperature gradient of the crystal) is adjusted such that void defects, OSFs (oxidation induced stacking faults), and dislocation clusters (interstitial silicon type dislocation defects) are eliminated from the pulled silicon single crystal. At this point, as shown in FIG. 21, the carbon concentration in the silicon single crystal is 3×10¹⁵ atoms/cm³ or less, and the allowable range of the growth condition V/G under which defect-free crystals can be obtained is expanded. Accordingly, even though V/G varies dynamically during crystal growth, the growth condition V/G is easy to control.

With the twenty-first invention, the carbon concentration in a silicon single crystal can be reduced to 3×10¹⁵ atoms/cm³ or less merely by utilizing and positioning the existing heat shield 108 in a single crystal pulling apparatus 101. Accordingly, compared to Prior Art 9 to 12, the cost of manufacturing the single crystal pulling apparatus 101 itself can be lowered, and the carbon concentration in the silicon single crystal can be stably lowered.

The present invention may also be such that the heat shield 108 is raised to position A where it touches the inner walls of the CZ furnace 102, and the heat shield 108 does not necessarily have to be in complete contact with the inner walls, and as long as the same gas flow as shown in FIG. 28 can be achieved, the upper end of the heat shield 108 may be in a state in which it is close to the inner walls of the CZ furnace 102 (about 0 to 30 mm away).

Another parameter that determines carbon concentration besides the position of the heat shield 108 is the crucible position C/P, and the carbon concentration can be controlled by varying the crucible position C/P. As shown by level \textcircled{4} in FIG. 33 (in which the position of the heat shield 108 is A and the crucible position C/P is −100 mm), the carbon concentration in the silicon single crystal can be further lowered by setting crucible position C/P negative, specifically, by positioning the upper end of the graphite crucible 103b lower than the upper end of the heater 109.

Another parameter that determines carbon concentration besides the position of the heat shield 108 is the flux of the argon gas 107, and the carbon concentration can be controlled by varying the flux of the argon gas 107. The carbon concentration in the silicon single crystal can be further lowered by increasing the flux of the argon gas 107.

With the present invention, when a gate valve 111 is closed during the melting step, it is preferable for the heat shield 108 and the crucibles 103a and 103b to be positioned at the positions indicated in FIG. 28 or FIG. 33 (level \textcircled{4}) or FIG. 30 (level \textcircled{1}), but when the gate valve 111 is not closed during the melting step, the heat shield 108 and the crucibles 103a and 103b may also be positioned at the positions indicated in FIG. 28 or FIG. 33 (level \textcircled{4}) or FIG. 30 (level \textcircled{1}). Furthermore, this same positioning may be performed in a step other than the melting step.

### BRIEF DESCRIPTION OF THE DRAWINGS

FIGS. 1A and 1B are diagrams that conceptually illustrate the defect formation mechanism;

FIG. 2 is a diagram of the relationship between the type of defect and the point defect (vacancy, interstitial silicon) concentration;

FIG. 3 is a graph of the relationship between the cooling rate, the void defect density, and the void defect size;

FIG. 4 is a graph of the relationship between V/G₁ and elapsed time, and illustrates prior art;

FIG. 5 is a graph of the relationship between the void defect density and the void defect size;

FIG. 6 is a graph of the relationship between the cooling rate at 1100° C. and the void defect size;

FIGS. 7A, 7B, and 7C are graphs of the relationship between V/G₁ and the radial position on a silicon wafer;

FIG. 8 is a graph of the relationship between the pulling rate, the solid-liquid interface shape, and the OSF occurrence pulling rate under ordinary conditions;

FIG. 9 is a graph of the relationship between the pulling rate, the solid-liquid interface shape, and the OSF occurrence pulling rate when a horizontal magnetic field was applied;

FIG. 10 is a graph of the relationship between the pulling rate, the solid-liquid interface shape, and the OSF occurrence pulling rate when a cooler was installed;

FIG. 11 is a graph of the lower limit rate at which no OSFs occurred when a cooler was installed;

FIG. 12 is a graph of the relationship between the pulling rate ratio and the void defect size at the crystal center when a cooler was installed;

FIGS. 13A, 13B, and 13C are graphs of the relationship between the pulling rate and the void defect size at the crystal center, and illustrate the effect of embodiments;

FIGS. 14A, 14B, 14C, and 14D show the pulling rate ratio when a cooler was installed, the presence or absence of an OSF region, and correspondence with histograms of LPD count per wafer;

FIG. 15 is a diagram illustrating the manufacturing apparatus in an embodiment;

FIG. 16 is a diagram illustrating the solid-liquid interface;

FIG. 17 is a table comparing a conventional COP reduction method with the method pertaining to the present invention;

FIG. 18 is a graph of the change in the shape of the solid-liquid interface when the silicon crystal rotational speed was varied;

FIG. 19 is a graph of the change in the shape of the solid-liquid interface when the crucible rotational speed was varied;

FIG. 20 is a graph of the relationship between the pulling rate and the solid-liquid interface shape for a silicon crystal with a different diameter from that in FIG. 8;

FIG. 21 is a graph of the distribution of defect types, correlated to the carbon concentration and growth condition;

FIG. 22 is a graph of the distribution of defect types, correlated to the growth rate (pulling rate) and the distance from the center of the crystal, when the carbon concentration was 3×10¹⁵ atoms/cm³;

FIG. 23 is a graph of the distribution of defect types, correlated to the growth rate (pulling rate) and the distance from the center of the crystal, when the carbon concentration was 6×10¹⁴ atoms/cm³;

FIG. 24 is a table of the (V/G)/(V/G)₀ value at the boundary at which the defect type changes, correlated to carbon concentration;

FIG. 25 is a side view of the apparatus constitution in an embodiment;

FIG. 26 is an oblique view of a heat shield;

FIG. 27 is a diagram of the mechanism for raising and lowering the heat shield;

FIG. 28 is a diagram of the flow of gas in an embodiment;

FIG. 29 is a diagram of the flow of gas in prior art;

FIG. 30 is a diagram of the flow of gas with positioning at level \textcircled{1};

FIG. 31 is a diagram of the flow of gas with positioning at level \textcircled{2};

FIG. 32 is a diagram of the flow of gas with positioning at level \textcircled{3};

FIG. 33 is a diagram of the flow of gas with positioning at level \textcircled{4};

FIG. 34 is a diagram of the flow of gas with positioning at level \textcircled{5};

FIG. 35 is a diagram of the flow of gas with positioning at level \textcircled{6};

FIG. 36 is a table of the position of the heat shield, the crucible position, and the carbon concentration ranking (from 1 to 6 in ascending order), correlated to the levels \textcircled{1} to \textcircled{6} in FIGS. 30 to 35; and

FIG. 37 is a table of the relationship between gas flux, crucible position, and carbon concentration.

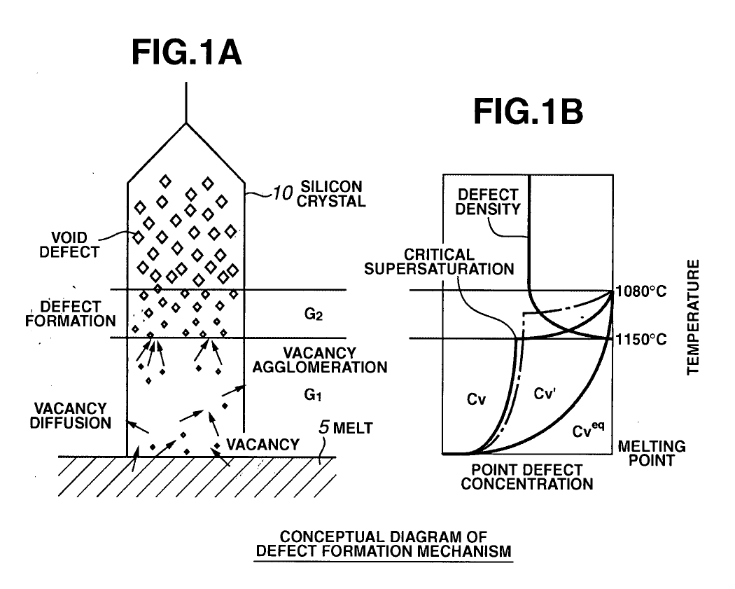

### BEST MODE FOR CARRYING OUT THE INVENTION

Embodiments of the present invention will now be described through reference to the drawings.

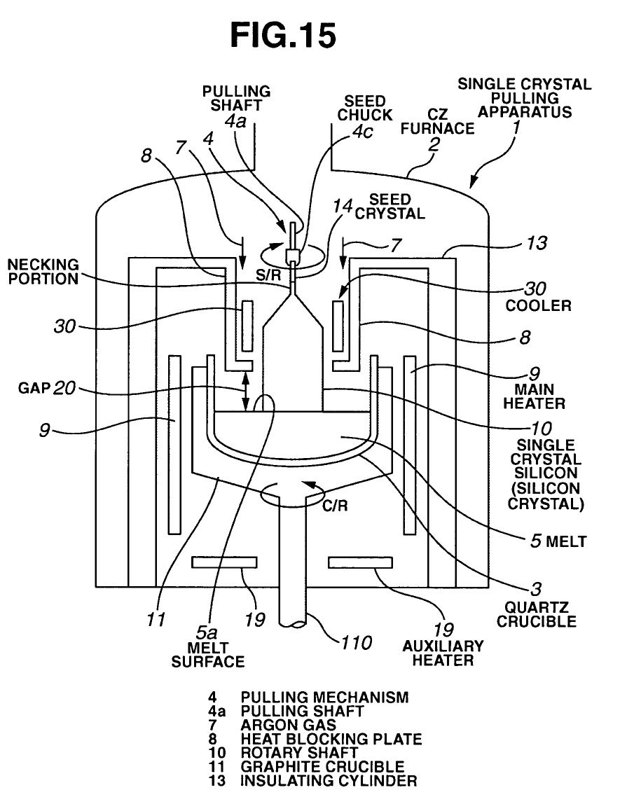

FIG. 15 is a side view illustrating an example of the constitution of an apparatus used for manufacturing silicon crystal in an embodiment.

As shown in FIG. 15, a single crystal pulling apparatus 1 of this embodiment is equipped with a CZ furnace (chamber) 2 as a vessel for pulling a single crystal.

A quartz crucible 3 in which raw material polycrystalline silicon is melted and held as a melt 5 is provided inside the CZ furnace 2. The outside of the quartz crucible 3 is covered by a graphite crucible 11. A main heater 9 for heating and melting the polycrystalline silicon raw material in the quartz crucible 3 is provided to the side on the outside of the quartz crucible 3. An auxiliary heater (bottom heater) 19 for supplementarily heating the bottom of the quartz crucible and preventing the solidification of the melt 5 at the bottom of the quartz crucible 3 is provided at the bottom of the quartz crucible 3. The main heater 9 and the auxiliary heater 19 are independently controlled in their output (power; kW), and the amount that they heat the melt 5 is also independently controlled. For instance, the temperature of the melt 5 is measured, the measured temperature is used as a feedback amount, and the outputs of the main heater 9 and the auxiliary heater 19 are controlled so that the temperature of the melt 5 will reach the target temperature.

An insulating cylinder 13 is provided between the main heater 9 and the inner walls of the CZ furnace 2.

A pulling mechanism 4 is provided above the quartz crucible 3. The pulling mechanism 4 includes a pulling shaft 4a and a seed chuck 4c at the distal end of the pulling shaft 4a. A seed crystal 14 is clamped in the seed chuck 4c.

Polycrystalline silicon (Si) is heated and melted inside the quartz crucible 3. The pulling mechanism 4 is actuated and a silicon crystal 10 (silicon single crystal) is pulled up from the melt 5. Specifically, the pulling shaft 4a is lowered until the seed crystal 14 clamped in the seed chuck 4c at the distal end of the pulling shaft 4a is immersed in the melt 5. After the seed crystal 14 has been wetted by the melt 5, the pulling shaft 4a is raised. The silicon crystal 10 grows as the seed crystal 14 clamped in the seed chuck 4c is pulled. During the pulling, the quartz crucible 3 is rotated by a rotary shaft 110 at a rotational speed of C/R. The pulling shaft 4a of the pulling mechanism 4 rotates at a rotational speed of S/R in the same or opposite direction as the rotary shaft 110.

The rotary shaft 110 can be driven vertically, allowing the quartz crucible 3 to be moved up and down to the desired position.

The inside of the CZ furnace 2 is kept under a vacuum (of about 20 Torr, for example) by isolating the inside of the furnace 2 from the outside atmosphere. Specifically, argon gas 7 is supplied as an inert gas to the CZ furnace 2 and exhausted by pump from an exhaust port in the CZ furnace 2. This keeps the inside of the furnace 2 at a specific reduced pressure.

Various kinds of evaporated material are generated within the CZ furnace 2 during the process of pulling a single crystal (one batch). Because of this, the argon gas 7 is supplied to the CZ furnace 2 to purge the evaporated material to the outside of the CZ furnace 2, thereby cleaning the inside of the CZ furnace 2 of this evaporated material. The supply flux of the argon gas 7 is set for each step in one batch.

The melt 5 is gradually used up as the silicon crystal 10 is pulled. As the melt 5 is used up, the contact surface area between the melt 5 and the quartz crucible 3 changes, and the amount of oxygen dissolved from the quartz crucible 3 changes. These changes affect the oxygen concentration distribution in the silicon crystal 10 being pulled. In order to prevent this, additional polycrystalline silicon raw material or monocrystalline silicon raw material may be supplied, either during or after the pulling, into the quartz crucible 3 in which some of the melt 5 has been used up.

A heat shield 8 (gas flow straightening cylinder) substantially in the form of an inverted truncated cone is provided around the silicon crystal 10 and above the quartz crucible 3. The heat shield 8 is supported by the insulating cylinder 13. The heat shield 8 guides the argon gas 7, which is used as a carrier gas supplied from above into the CZ furnace 2, toward the center of the melt surface 5a, and then guides it through the melt surface 5a to the peripheral edge of the melt surface 5a. The argon gas 7 is exhausted from an exhaust port provided at the lower part of the CZ furnace 2 along with gas evaporated from the melt 5. This stabilizes the gas flow rate over the liquid surface, and keeps the oxygen evaporated from the melt 5 in a stable state.

The heat shield 8 thermally insulates and shields the seed crystal 14 and silicon crystal 10 being grown from the seed crystal 14 from the radiant heat generated by high-temperature components such as the quartz crucible 3, the melt 5, and the main heater 9. The heat shield 8 also prevents the growth of the single crystal from being hindered by the adhesion of impurities (such as silicon oxide) generated within the furnace to the silicon crystal 10. The size of the gap 20 between the melt surface 5a and the lower end of the heat shield 8 can be adjusted by raising or lowering the rotary shaft 110 and varying the vertical position of the quartz crucible 3. The gap 20 may also be adjusted by moving the heat shield 8 up or down with an elevator apparatus.

A cooler 30 for cooling the silicon crystal 10 is provided above the silicon melt 5 so as to surround the silicon crystal 10 at a distance of 30 to 500 mm from the silicon melt 5.

As will be discussed below, the parameters V/G₁ (V: growth rate, G₁: axial temperature gradient near the melting point of the silicon crystal 10), V·G₂ (V: growth rate, G₂: axial temperature gradient in the void defect occurrence temperature zone of the silicon crystal), the growth rate V, the axial temperature gradient G₁ near the melting point of the silicon crystal 10, and the radial distribution of the axial temperature gradient G₁ near the melting point of the silicon crystal 10 can be controlled by adjusting the gap 20, the pulling rate V of the pulling shaft 4a, and the cooling amount of the cooler 30.

The oxygen concentration (atoms/cm³) in the silicon crystal 10 is controlled by adjusting the crucible rotational speed C/R, the pulling shaft rotational speed S/R, the argon gas flux, the pressure inside the furnace, and so forth.

Silicon wafers 100 are obtained by using a cutting apparatus to cut an ingot of the silicon crystal 10 manufactured with the apparatus shown in FIG. 15.

### First Embodiment

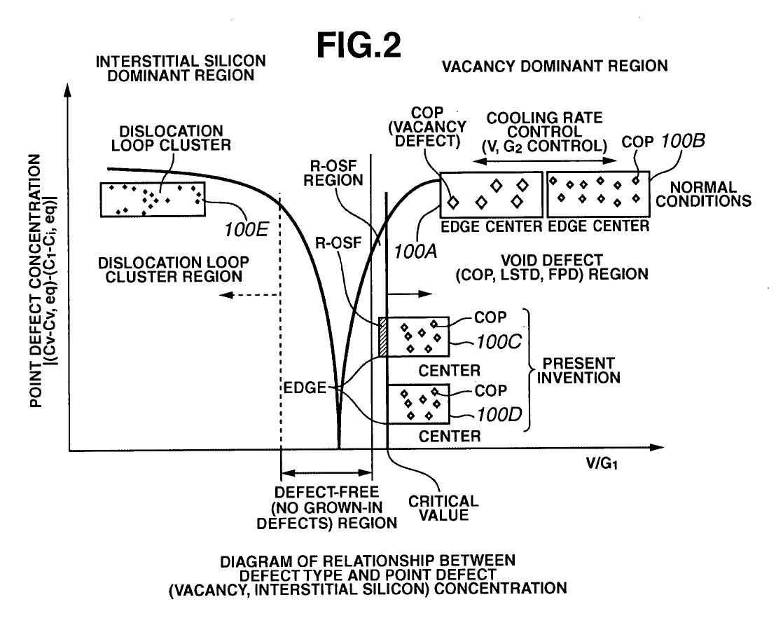

100D shown in FIG. 2 is a silicon wafer in the first embodiment. The silicon wafer 100D in this embodiment is manufactured such that no OSF region is present anywhere in the plane of the silicon wafer, from the planar center to the edge.

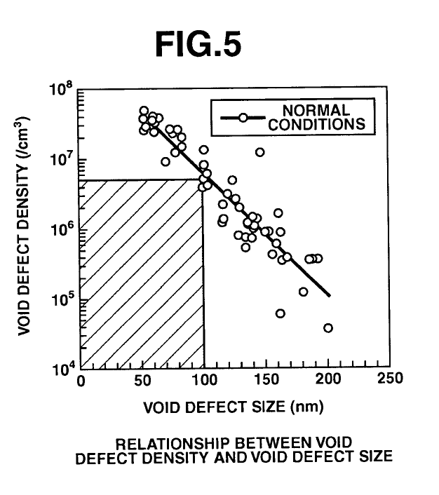

The region indicated by hatching in FIG. 5 indicates the range of the average void defect density and the average void defect size in the entire plane of the silicon wafer 100D of the first embodiment. The silicon wafer 100D of the present invention has an average void defect density in the entire wafer plane of 5×10⁶/cm³ or less, and has an average void defect size of 100 nm or less.

The silicon crystal 10 in the first embodiment has a diameter of 200 mm, and is grown by pulling at a rate V of from 1.11 to 1.45 mm/min.

With this first embodiment, since the average void defect density in the entire wafer plane is 5×10⁶/cm³ or less, and the average void defect size is 100 nm or less, deterioration in device characteristics that would otherwise be caused by void defects can be eliminated. Also, since no OSF region is present anywhere in the plane of the silicon wafer, deterioration in device characteristics that would otherwise be caused by OSFs can be eliminated. Also, since the silicon crystal 10 is grown by pulling at a high rate of 1.11 to 1.45 mm/min, productivity is enhanced.

We will now examine the conditions for manufacturing this silicon wafer 100D.

As discussed above, at present, the void defect density and size are controlled by varying the cooling rate V·G₂ in the void defect occurrence temperature zone in a high V/G₁ region of relatively stable vacancy concentration in which the OSF region has been moved to the outer periphery of the crystal, as shown by 100A and 100B in FIG. 2.

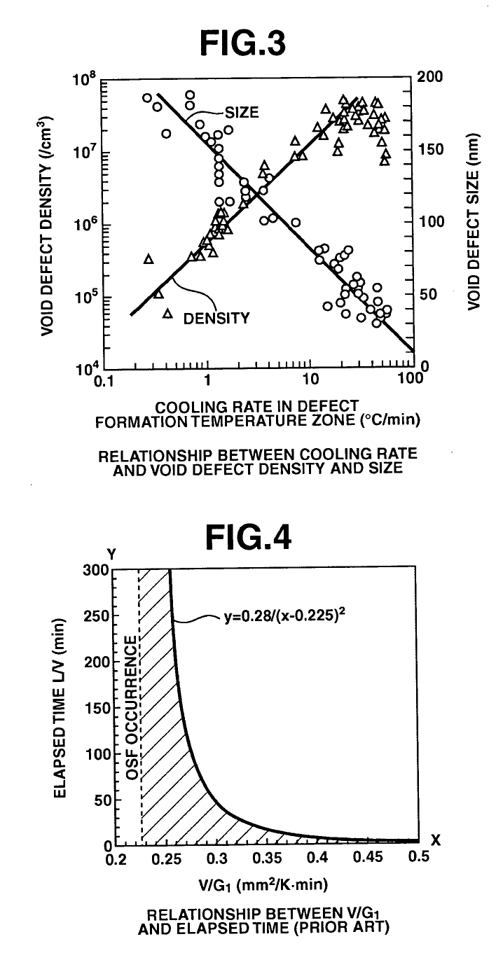

As shown in FIG. 3, the relationship between the void defect density and size is a roughly inversely proportional relationship; the greater is the cooling rate V·G₂ the smaller is the defect size (high V·G₂ effect), and the lower is the cooling rate V·G₂ the larger is the defect size. In the region of high V/G₁, the total vacancy concentration constituting void defects is substantially constant, V/G₁ remains virtually unaffected, and the defect density and size are determined just by the cooling rate V·G₂ as shown by 100A and 100B in FIG. 2.

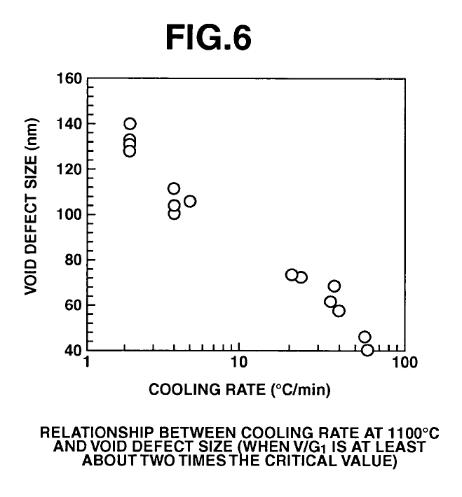

FIG. 6 is a graph of the relationship between the cooling rate at 1100° C. and the void defect size, when V/G₁ is at least twice the critical value. At a high V/G₁ such as this, the defect size can be reduced merely by greatly changing V·G₂ which expresses the cooling rate (high V·G₂ effect).

However, in the region close to the critical value in which V/G₁ changes from a void defect region to an OSF region, as shown by 100C and 100D, V/G₁ approaches the critical value, and the lower is the total vacancy concentration, the more pronounced is the reduction in defect size due to the effect of V/G₁ (low V/G₁ effect). In the region where V/G₁ is close to the critical value, the smaller is V/G₁ and the larger is V·G₂, the smaller is the size of the void defects.

Accordingly, two possible ways to shrink the defect size are to mainly increase V·G₂ and to mainly decrease V/G₁. Merely varying the growth rate V, however, does not allow both V·G₂ to be increased and V/G₁ to be decreased, so some way to increase G₁ is necessary, as discussed below.

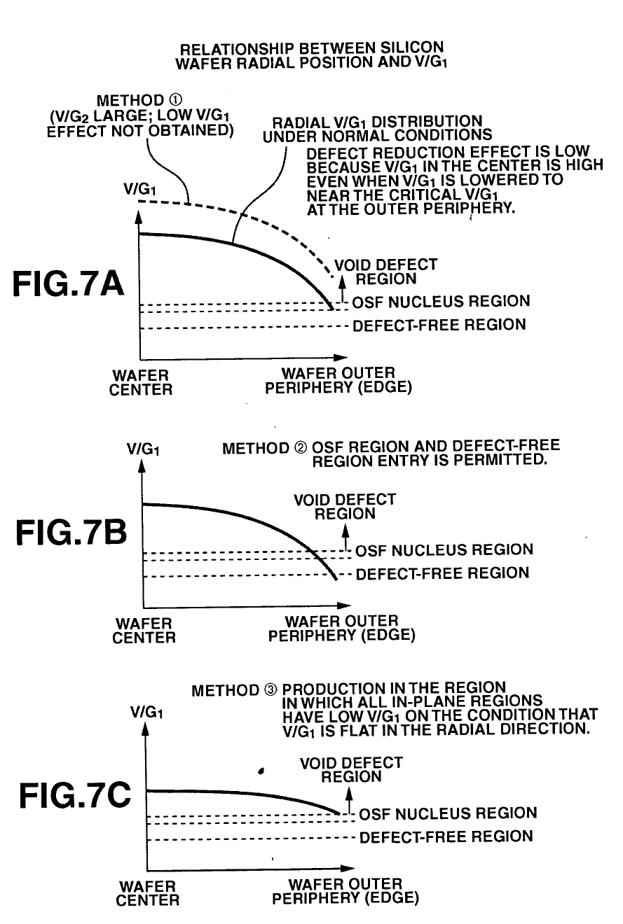

FIGS. 7A to 7C consists of graphs of the distribution of V/G₁ between the silicon wafer center and the silicon wafer outer periphery (edge). FIGS. 7A to 7C will be referred to in the following description.

One effective way to increase V·G₂ is to perform the pulling at a high rate by raising the limit rate Vmax of the growth rate V at which growth is possible without deformation of the silicon crystal 10, and by raising G₂ with the cooler 30 (method \textcircled{1}).

An advantage to this method \textcircled{1} is that the pulling rate is high, and productivity is better.

However, as indicated by the broken line in FIG. 7A, with method \textcircled{1}, V/G₁ is far larger than the critical value and no low V/G₁ effect is obtained, so there is a limit to how much the void defect size and density can be reduced.

With a method in which V/G₁ is decreased, the low V/G₁ effect will not be pronounced unless V/G₁ is lowered to near the critical value at which the type of defect changes from a void defect to an OSF. This corresponds to the fact that the silicon wafer edge was moved to near the critical value with the silicon wafer 100A in FIG. 2.

Under the pulling conditions normal employed, as indicated by the solid line in FIG. 7A, even if the V/G₁ at the silicon wafer outer periphery is lowered to the critical value, the difference from the V/G₁ at the silicon wafer center will be great, so V/G₁ will be high at the silicon wafer center and no low V/G₁ effect will be obtained. Accordingly, there is a limit to how much the void defect size and density can be reduced at the silicon wafer center.

The following methods are possible ways to solve this problem.

Method \textcircled{2}

As indicated by the solid line in FIG. 7B, at the silicon wafer outer periphery, entry into the OSF region and defect-free region is allowed, V/G₁ is decreased at the silicon wafer center, and a low V/G₁ effect is obtained.

Method \textcircled{3}

As indicated by the solid line in FIG. 7C, so that there will be no difference in V/G₁ between the center of the silicon wafer and the outer periphery, V/G₁ in the silicon wafer plane is uniformly at or above a certain level, V/G₁ is decreased over the entire silicon wafer plane, and a low V/G₁ is obtained. This method \textcircled{3} corresponds to Prior Art 2 discussed above.

With the above method \textcircled{2}, the number of void defects is reduced by narrowing the region in which void defects are present in the wafer plane. However, a problem with this silicon crystal 10 is that an OSF region is present. OSF nuclei can be prevented from materializing as OSFs in the silicon wafer 100 after heat treatment by keeping the oxygen concentration low in the silicon crystal 10, but there is the danger that insufficient oxygen precipitation will result in insufficient gettering capability. Also, productivity is lower because of a decrease in the growth rate V as compared to when the silicon crystal 10 is pulled under ordinary conditions.

With the above method \textcircled{3}, the void defect size is reduced over the entire wafer plane. However, the pulling rate V is lower compared to manufacture under ordinary conditions in which V/G₁ in the wafer plane is uniformly at or above a certain level. Experimentation by the inventors has revealed that when the silicon crystal 10 with a diameter of 200 mm is pulled, the pulling rate V cannot be raised over 0.8 mm/min. Thus, there is the danger that this method \textcircled{3} will lead to lower productivity.

Prior Art 1 will now be examined.

In FIG. 4, the range of the growth condition V/G₁ and V·G₂ at the center of the silicon crystal 10 in Prior Art 1 is indicated by hatching. In Prior Art 1, V·G₂ is defined by the void defect occurrence temperature zone elapsed time IV (L: temperature region length), which is the inverse [of V·G₂].

FIG. 4 plots the elapsed time LIV in the void defect formation temperature zone versus V/G₁, and shows a threshold where y=0.28/(x−0.225)² (x: horizontal axis, y: vertical axis), at which the density of particles whose size is at least 0.10 μm is one per square centimeter. In the region indicated by hatching, whose boundary is this threshold, there is no occurrence of R-OSF and the density of particles whose size is at least 0.10 μm one per square centimeter or less.

In Prior Art 3 it is stated that the critical value and the radial distribution of V/G₁ vary with the shape of the solid-liquid interface, which is the boundary between the silicon melt and the silicon crystal 10.

The hatched region in FIG. 4 is the region in which the defect size and density decrease at a critical value under certain conditions, but depending on the shape of the solid-liquid interface, a decrease in defect size and density may not always occur in the hatched region shown in FIG. 4.

V/G₁ in Prior Art 1 is the value at the crystal center, and the radial distribution of V/G₁ is not considered at all. Consequently, if there is a change in the shape of the solid-liquid interface, the radial distribution of V/G₁ will be different even though the V/G₁ value is the same at the crystal center, and as a result, there is sometimes an OSF region, rather than a void defect region, at the crystal edge. If the solid-liquid interface shape differs, there may be a difference in the void defect size at the crystal edge.

Thus, it cannot be concluded that the hatched region in FIG. 4 shown in Prior Art 1 will always be a void defect region in the entire wafer plane, or that the defect size and density will always decrease.

Specifically, although applying Prior Art 1 does indeed lower the void defect size and density by creating a low V/G₁ at the crystal center under the conditions shown in FIG. 4, it is conceivable that V/G₁ will drop under the critical value and R-OSFs will occur at the crystal edge if V/G₁ is made low at the crystal center, just as in FIG. 7B.

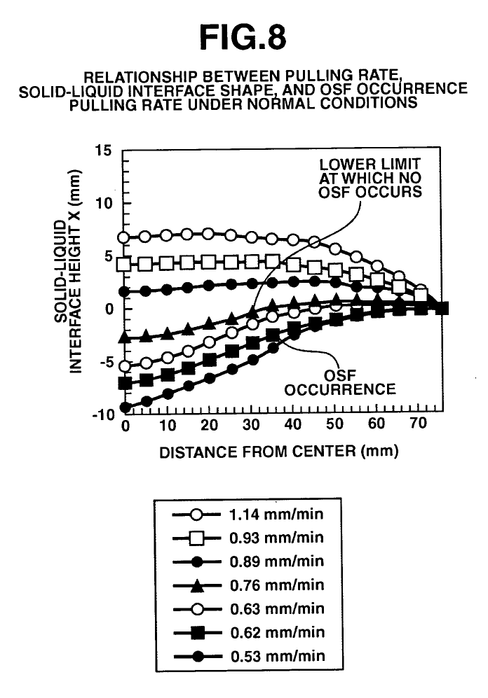

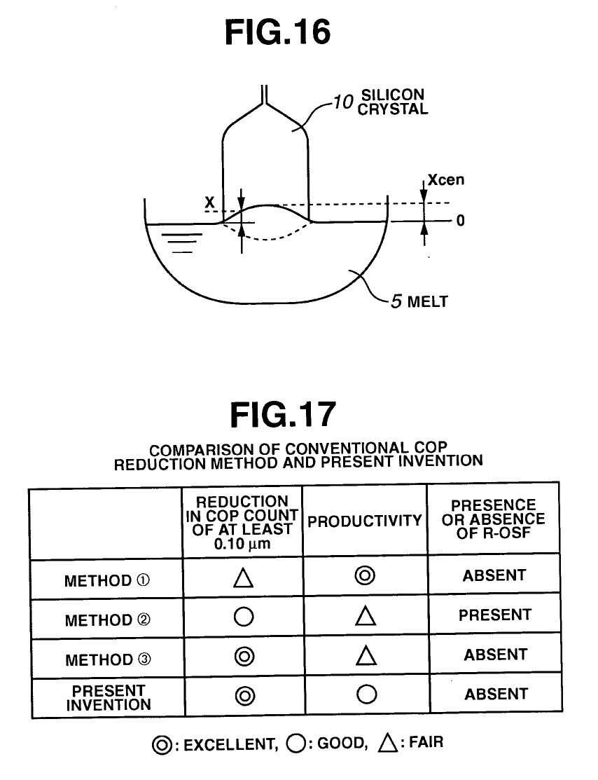

FIG. 8 shows the results of an experiment in which the change in the solid-liquid interface shape was examined under ordinary pulling conditions (no magnetic field applied, no cooler installed). The horizontal axis in FIG. 8 is the distance from the center of the silicon crystal 10 (radial distance), and the vertical axis is the height X of the solid-liquid interface at various points. The solid-liquid interface height X is defined in FIG. 16 as the solid-liquid interface center height (amount of protrusion) Xcen. When the solid-liquid interface center height Xcen is a positive value, the solid-liquid interface protrudes upward, and when the solid-liquid interface center height Xcen is a negative value, the solid-liquid interface protrudes downward. FIG. 8 shows the solid-liquid interface shape at various growth rates when the growth rate V was varied between 0.53 and 1.14 mm/min, and shows the growth rate at which OSFs occur, and the solid-liquid interface shape at that point.

As shown in FIG. 8, under ordinary conditions, as the pulling rate V is lowered in order to achieve a low V/G₁, the solid-liquid interface gradually changes from an upwardly protruding shape to a downwardly protruding shape. When the pulling rate V is lowered to the critical value at which R-OSFs occur, the solid-liquid interface shape protrudes downward. The pulling rate V at this point was 0.76 mm/min.

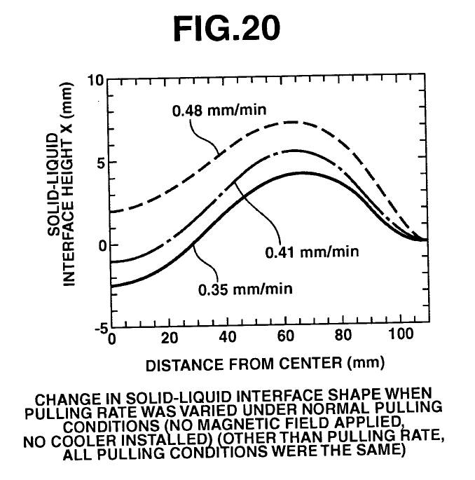

FIG. 20 shows the results of an experiment in which the change in the solid-liquid interface shape was examined when a silicon crystal with a different diameter from that in FIG. 8 was grown under ordinary pulling conditions (no magnetic field applied, no cooler installed). The horizontal and vertical axes in FIG. 20 correspond to the horizontal and vertical axes in FIG. 8. FIG. 20 shows the solid-liquid interface shape at various growth rates when the growth rate V was changed to 0.35, 0.41, and 0.48 mm/min. It can be seen that the solid-liquid interface shape is convex downward in this growth rate region.

The inventors discovered here that when the solid-liquid interface shape is convex upward, the G₁ distribution in the wafer plane is uniform at or above a certain level, and the radial distribution of V/G₁ is uniform at or above a certain level, but conversely, when the solid-liquid interface shape is convex downward, there is variance in the G₁ distribution in the wafer plane, and the radial distribution of V/G₁ is not uniform.

Under ordinary conditions, the solid-liquid interface is convex downward when V/G₁ is lowered to the critical value as shown in FIG. 8, so it is thought that R-OSFs tend to occur at the wafer edges because of the difference in the G₁ in the wafer plane. That is, just as in FIG. 7B, even though V/G₁ is lowered at the crystal center, V/G₁ drops below the critical value at the crystal edges, and R-OSFs occur.

Therefore, to avoid this, one way to make the solid-liquid interface convex upward regardless of the pulling rate V is to apply a horizontal magnetic field of at least 2500 G to the silicon melt 5 (method \textcircled{4}).

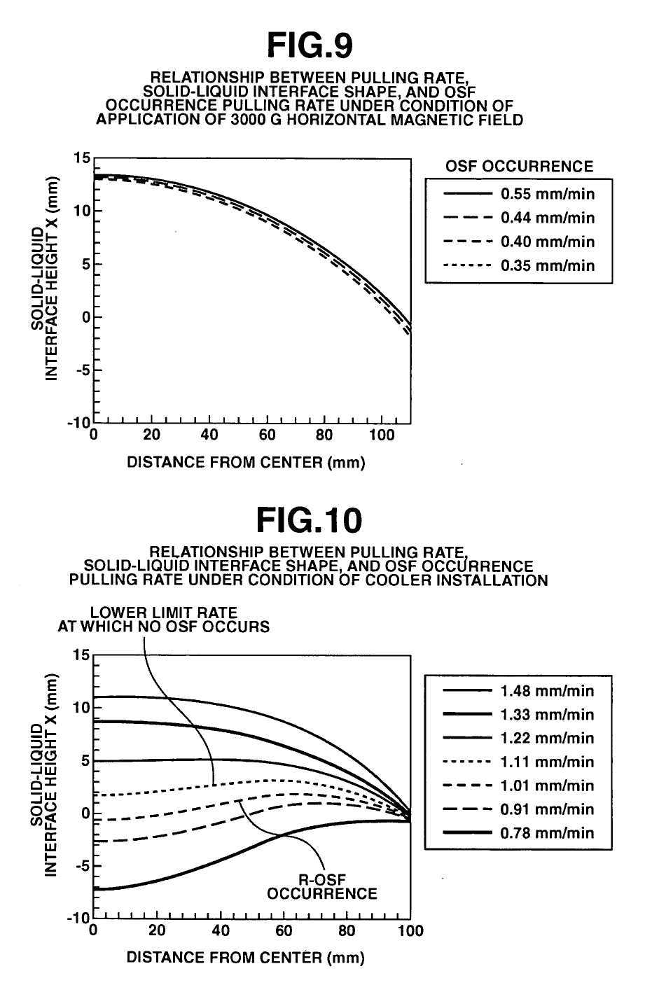

FIG. 9 shows the results of an experiment in which the change in the solid-liquid interface shape was examined under pulling conditions in which the gap 20 was set at 57 mm, the crucible rotational speed C/R was set at 3 rpm, and a horizontal magnetic field of 3000 G was applied to the silicon melt 5. The horizontal and vertical axes in FIG. 9 correspond to the horizontal and vertical axes in FIG. 8. The growth rate V was varied between 0.35 and 0.55 mm/min.

As shown in FIG. 9, the solid-liquid interface can be made convex upward regardless of the pulling rate V on the condition that a horizontal magnetic field is applied.

Cooling the silicon crystal 10 with the cooler 30 is a way to make the solid-liquid interface convex upward in a state in which the pulling rate V is kept high, without decreasing productivity (method \textcircled{5}).

FIG. 10 shows the results of an experiment in which the change in the solid-liquid interface shape was examined when a silicon crystal with a diameter of 200 mm was produced under pulling conditions in which the gap 20 was set at 30 mm, the crucible rotational speed C/R was set at 4 rpm, the silicon crystal 10 rotational speed SIR was set at 13 rpm, and the cooler 30 was disposed 80 mm above the silicon melt 5. The horizontal and vertical axes in FIG. 10 correspond to the horizontal and vertical axes in FIG. 8. The growth rate V was varied between 0.78 and 1.48 mm/min.

As shown in FIG. 10, under a condition in which the silicon crystal 10 is cooled with the cooler 30, the solid-liquid interface shape is convex upward even if the pulling rate V is lowered to the critical value at which R-OSFs occur. As can be seen from a comparison with FIG. 8, the lower limit pulling rate V when V/G₁ was lowered to the critical value was a high 1.11 mm/min.

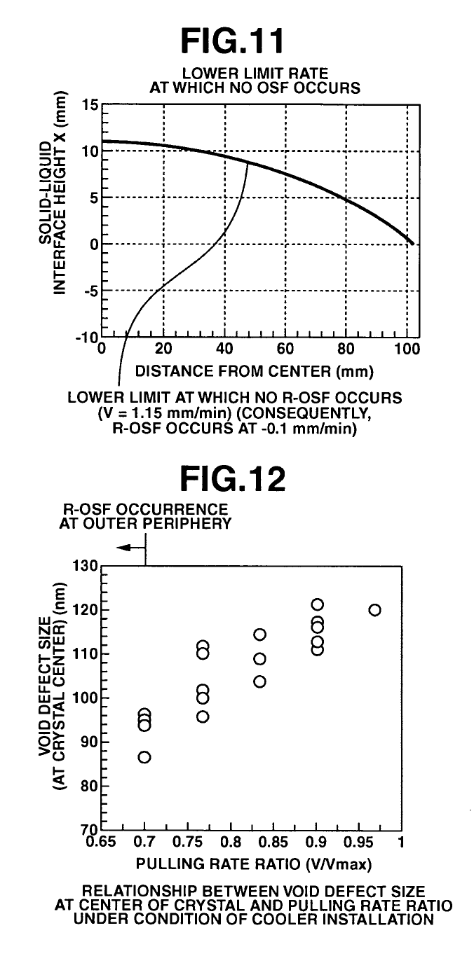

FIG. 11 shows the results of examining the pulling rate V when the conditions were different from those in FIG. 10, so that the crucible rotational speed C/R was set at 1 rpm, and V/G₁ was lowered to near the critical value. The pulling rate V at which no R-OSF occurred was 1.15 mm/min or more. It can be seen that the solid-liquid interface was convex upward at a pulling rate at which no R-OSF occurred as compared to FIG. 10. This tells us that adjusting the crucible rotational speed in addition to installing the cooler is effective in terms of making the solid-liquid interface convex upward.

The crucible rotational speed C/R and the silicon crystal rotational speed S/R were examined to see what effect these parameters would have on the shape of the solid-liquid interface.

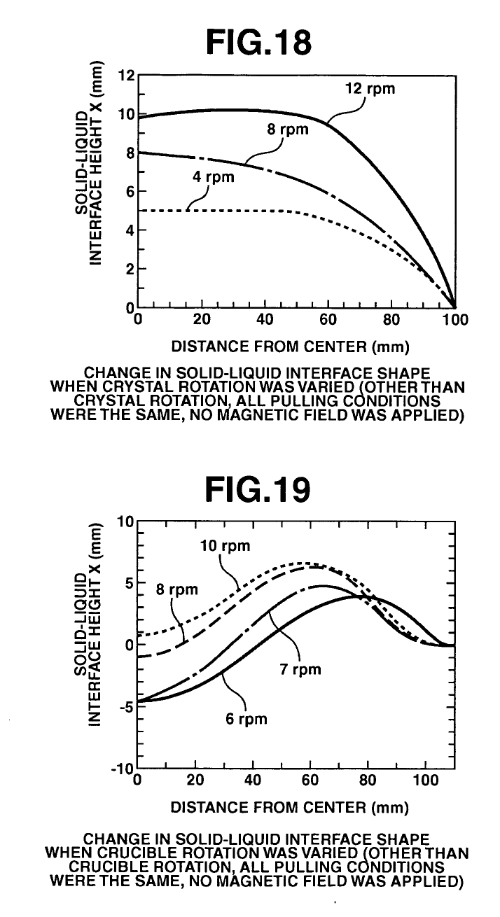

FIG. 18 shows the results of an experiment in which the change in the solid-liquid interface shape was examined when just the silicon crystal rotational speed S/R was varied, no magnetic field was applied, and the crucible rotational speed C/R and other pulling conditions were the same. The horizontal and vertical axes in FIG. 18 correspond to the horizontal and vertical axes in FIG. 8. The silicon crystal rotational speed S/R was varied to 4, 8, and 12 rpm.

As shown in FIG. 18, the higher the silicon crystal rotational speed S/R was raised, the better was the effect in terms of making the solid-liquid interface convex upward.

FIG. 19 shows the results of an experiment in which the change in the solid-liquid interface shape was examined when just the crucible rotational speed C/R was varied, with no magnetic field applied and with the silicon crystal rotational speed S/R and other pulling conditions the same. The horizontal and vertical axes in FIG. 19 correspond to the horizontal and vertical axes in FIG. 8. The crucible rotational speed C/R was varied to 6, 7, 8, and 10 rpm.

As shown in FIG. 19, the higher the crucible rotational speed C/R was raised, the better was the effect in terms of making the solid-liquid interface convex upward.

Therefore, the solid-liquid interface shape can be made convex upward when the pulling rate V has been lowered to the critical value at which R-OSFs occur by adjusting the silicon crystal rotational speed S/R and the crucible rotational speed C/R in addition to installing the cooler 30.

Thus, the pulling rate V at which no R-OSFs occur in the silicon wafer plane can be raised over that under ordinary conditions (FIG. 8) by adjusting the silicon crystal rotational speed S/R and the crucible rotational speed C/R in addition to the condition of installing a cooler. This is because cooling the silicon crystal 10 with the cooler 30 increases G₁ and allows the rate V to be raised when V/G₁ has decreased to the critical value.

FIG. 12 shows the relationship between the pulling rate ratio V/Vmax and the void defect size at the silicon crystal center when the silicon crystal 10 was cooled with the cooler 30.

The pulling rate ratio V/Vmax is the ratio of the pulling rate V to the limit rate Vmax at which the silicon crystal 10 deforms.

As shown in FIG. 12, the more the pulling rate V is lowered and the pulling rate ratio V/Vmax is decreased, the smaller is the defect size.

A decrease in the pulling rate V means a decrease in V·G₂, and therefore means an increase the void defect size as far as the V·G₂ parameter is concerned, but in addition to the negative effect produced by this decrease in V·G₂, there is also the low V/G₁ effect, which is believed to shrink the defect size.

Based on the above results, it is preferable to manufacture the silicon wafer 100D by the following method.

Manufacturing Method 1

With this manufacturing method 1, the method \textcircled{5} is employed, and the cooler 30 is installed inside the CZ furnace 2. The cooler 30 is disposed so as to surround the silicon crystal 10 at a distance of 30 to 500 mm from the silicon melt 5. The diameter of the silicon crystal 10 here was 200 mm.

The gap 20 between the silicon melt surface 5a and the lower end of the heat shield 8 is set to between 20 and 100 mm.

The pulling rate V of the silicon crystal 10 by the pulling mechanism 4 is adjusted, and the cooling amount of the cooler 30 is adjusted, so that the growth condition V/G₁ is lowered to near the critical value in a state in which the axial temperature gradient G₁ near the melting point of the silicon crystal 10 is increased, and the solid-liquid interface is convex upward with respect to the melt surface within a range of growth rate V of from 1.11 to 1.45 mm/min. The solid-liquid interface center height Xcen here is preferably from 0 to 20 mm. The silicon crystal rotational speed S/R and the crucible rotational speed C/R are adjusted as needed.

With this manufacturing method, as described with FIG. 10, cooling the silicon crystal 10 with the cooler 30 increases G₁, and allows the rate V when V/G₁ has been lowered to near the critical value to be kept high, at at least 1.11 mm/min. As described with FIG. 12, however, in order to obtain the effect of reducing the void defect size, the pulling rate V is preferably close to the lower limit rate of 1.11 mm/min at which no OSFs occur. Even though the rate is low, it is still sufficient compared to the lower limit pulling rate at which no OSFs occurred under ordinary pulling conditions (0.76 mm), so there is no decrease in productivity.

With this manufacturing method, since the growth rate V/G₁ is lowered to near the critical value in a state in which the solid-liquid interface is convex upward with respect to the melt surface, just as in FIG. 7C, the radial distribution of V/G₁ in the wafer plane is uniform at or above a certain level, and no OSFs occur and the low V/G₁ effects affords a reduction in void defect size and density. Furthermore, since the rate V can be kept higher than under ordinary conditions, V·G₂ is larger, and the high V·G₂ effect allows the defect size to be further decreased (see FIG. 3). Therefore, the void defect size and density over the entire plane of the silicon wafer 100D can be reduced to the level indicated by the hatching in FIG. 5.

The fact that the lateral width of the silicon wafer 100D shown in FIG. 2 is narrower than the lateral width of the silicon wafers 100A and 100B obtained under ordinary conditions indicates that V/G₁ has become uniform within the wafer plane, and the void defect size and density have been uniformly decreased within the wafer plane.

Furthermore, with this manufacturing method 1, since the cooler 30 is used to make the solid-liquid interface convex upward (method \textcircled{5}), the apparatus cost can be kept lower than when the same thing is accomplished by application of a horizontal magnetic field (method \textcircled{4}).

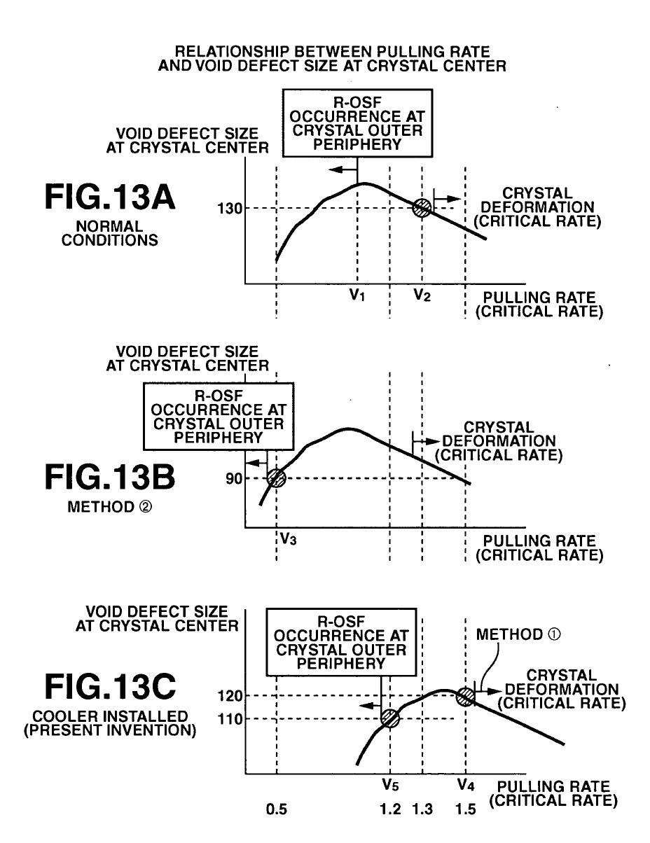

The effect of manufacturing method 1 will now be described through reference to FIGS. 13A, 13B and 13C.

FIGS. 13A, 13B and 13C show the relationship between the pulling rate and the void defect size at the crystal center. FIGS. 13A to 13C correspond to FIGS. 7A to 7C.

Under ordinary conditions, as shown in FIG. 13A, when the pulling rate V is decreased, OSFs end up occurring at the crystal outer periphery at a rate of V₁, which is before a low V/G₁ effect can be sufficiently obtained at the crystal center. Accordingly, the defect size is decreased by raising the rate V to the pulling rate V₂ at which no low V/G₁ effect is obtained, but a high V·G₂ effect is obtained. However, there is a limit to how much the defect size can be decreased with a high V·G₂ effect alone.

With method \textcircled{2}, as shown in FIG. 13B, a sufficient low V/G₁ effect can be obtained at the crystal center and the defect size can be sufficiently decreased by lowering the pulling rate V to obtain V₃. However, there is the danger that OSFs will occur at the crystal outer periphery, and a decrease in the pulling rate adversely affects productivity.

In contrast, with the present invention in which the cooler 30 is used, as shown in FIG. 13C, the defect size can be sufficiently decreased because the pulling rate V can be kept at a high level (V₅) and a low V/G₁ effect is obtained. In contrast, with method (D, the cooler raises G₂ and raises the limit rate Vmax, so it is possible to attain an extremely high rate of V₄ that is near the limit rate Vmax, and productivity improves, but since a low V/G₁ effect cannot be obtained with a high V·G₂ effect alone, there is a limit to how much the defect size can be decreased.

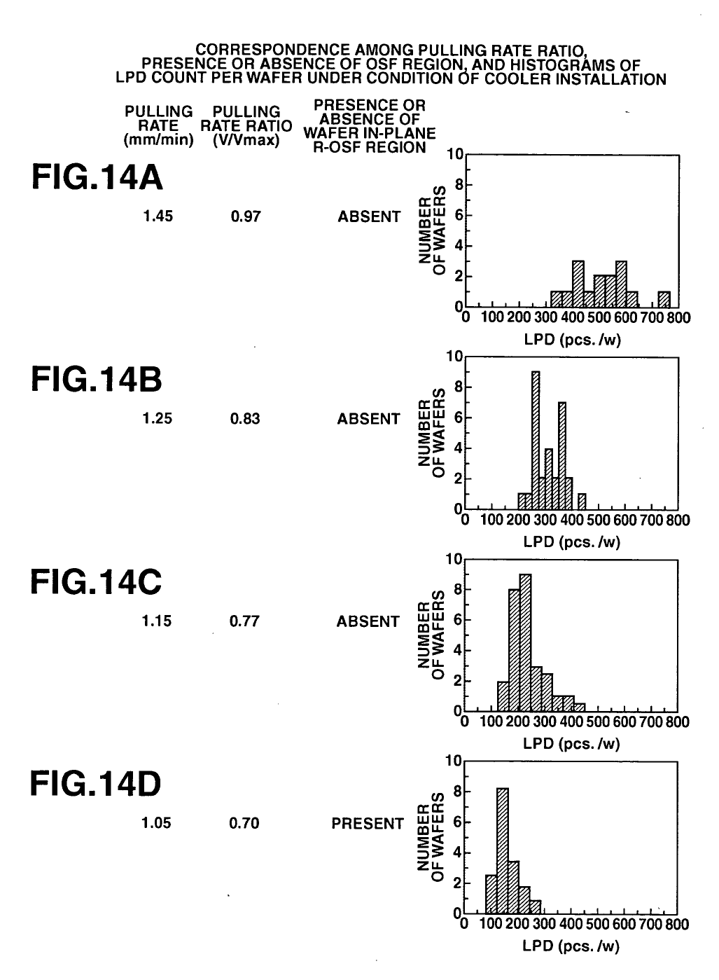

FIGS. 14A, 14B, 14C, and 14D show whether an R-OSF region was present in the wafer plane when the pulling rate was varied between 1.45 mm/min (pulling rate ratio V/Vmax=0.97), 1.25 mm/min (pulling rate ratio V/Vmax=0.83), 1.15 mm/min (pulling rate ratio V/Vmax=0.77), and 1.05 mm/min (pulling rate ratio V/Vmax=0.70), and histograms of LPD count per wafer.

The horizontal axis in these histograms is the number of particles at least 0.10 μm in size per wafer, and the vertical axis is the wafer count corresponding to each particle count.

It can be seen from FIGS. 14A to 14D that as the pulling rate V was decreased from 1.45 to 1.05 mm/min, there is a decrease in the number of large void defects per wafer. It can also be seen that OSFs occur in the wafer plane (the lower limit is 1.11 mm/min, as shown in FIG. 10) at a pulling rate of from 1.15 to 1.05 mm/min.

Next, the effect of this embodiment will be compared with that of Prior Art 1 and Prior Art 2 (method \textcircled{3}).

In Prior Art 1, the shape of the solid-liquid interface and the radial distribution of V/G₁ are not taken into account whatsoever, so the hatched region in FIG. 4 was not necessarily a region in which the void defect size and density could be reduced. With this embodiment, however, the solid-liquid interface is made convex upward and the radial distribution of V/G₁ is made uniform by adjusting the amount of cooling of the cooler 30, so defect size and density can be precisely reduced over the entire wafer plane. Accordingly, the device yield is higher because there are fewer defective devices.

Let us now make a comparison with Prior Art 2.

Near the solid-liquid interface of a growing silicon crystal, thermal balance is achieved under the Stefan conditions expressed by the following equation.
Kₛ·Gₛ=H·V+K_{L}·G_{L}
Kₛ: thermal conductivity of crystal
K_{L}: thermal conductivity of melt
Gₛ: temperature gradient of crystal
G_{L}: temperature gradient of melt
H: latent heat of solidification
V: pulling rate

With Prior Art 2 (method \textcircled{3}), the V/G₁ distribution in the crystal radial direction is uniform, but it is generally necessary to suppress the heat that escapes from the surface of the crystal in order to make the V/G₁ distribution uniform. Consequently, the expulsion of the latent heat of solidification is weakened, Kₛ·Gₛ in the above equation becomes smaller, and the pulling rate V cannot be raised. This in turn results in a decrease in the cooling rate in the void defect occurrence temperature zone, leading to a drop in V·G₂. This therefore hinders the reduction of void defects and adversely affects productivity. In contrast, with this embodiment, since the silicon crystal 10 is cooled with the cooler 30, G₁ is larger, V/G₁ can be reduced even if the pulling rate V is increased, and the interface shape is made convex upward, so the in-plane distribution of V/G₁ can be kept substantially uniform. Also, since the pulling rate V is high, V·G₂ can be increased. Accordingly, void defects can be reduced better and productivity can be increased as compared to Prior Art 2.

FIG. 17 is a table comparing the present invention with method \textcircled{1}, method \textcircled{2}, and method \textcircled{3} (Prior Art 2) in terms of reduction in COP count with a size of 0.10 μm or larger, productivity, and the presence of R-OSFs. In FIG. 17, the ⊚ symbol means “excellent,” ◯ means “good,” and Δ means “fair.” As shown in FIG. 17, the present invention overall received the best evaluation compared to the other methods.

Manufacturing Method 2

The silicon wafer 100D may be manufactured in the same manner as in Manufacturing Method 1 by applying the above-mentioned method G). In this case, control was performed in the same manner as in Manufacturing Method 1, except that a horizontal magnetic field of at least 2500 G was applied to the silicon melt 5 so as to make the solid-liquid interface convex upward. With Manufacturing Method 2, the solid-liquid interface can be made convex upward regardless of the pulling rate V, which affords greater freedom to the pulling rate V.

With the first embodiment discussed above, the intent was to avoid the occurrence of OSFs in the silicon wafer. However, even if there is an OSF region in terms of the crystal structure, if the OSF nuclei do not materialize into OSFs in the course of manufacturing a device, this may not pose any problem in terms of the characteristics of the silicon wafer. Specifically, it is known that R-OSF nuclei are oxygen precipitates in a silicon crystal, so it is possible to prevent their materialization into OSFs by decreasing the oxygen concentration in the silicon crystal, or by performing a heat treatment capable of eradicating the OSF nuclei after the production of the silicon wafer. To this end, the following manufacturing method may be employed.

### Second Embodiment

100C in FIG. 2 is the silicon wafer in the second embodiment. The silicon wafer 100C in this embodiment is manufactured such that no OSFs are present in the plane of the wafer at least from the center of the plane up to 10 mm from the outer periphery.

The region indicated by hatching in FIG. 5 indicates the range of the average void defect density and the average void defect size in the region to the inside of R-OSF of the silicon wafer 100C of the second embodiment. The silicon wafer 100C in the second embodiment has an average void defect density in the region to the inside of R-OSF of 5×10⁶/cm³ or less, and has an average void defect size of 100 nm or less.

The manufacturing method in the second embodiment is as follows.

Manufacturing Method 3

With this Manufacturing Method 3, the above-mentioned method \textcircled{5} is applied, and the cooler 30 is installed inside the CZ furnace 2. The diameter of the silicon crystal 10 is 200 mm.

The pulling rate V of the silicon crystal 10 by the pulling mechanism 4 is adjusted, and the cooling amount of the cooler 30 is adjusted, so that the growth condition V/G₁ is lowered to near the critical value in a state in which the axial temperature gradient G₁ near the melting point of the silicon crystal 10 is increased.

With this manufacturing method, as described with FIG. 10, cooling the silicon crystal 10 with the cooler 30 increases G₁, and allows the rate V when V/G₁ has been lowered to near the critical value to be kept high. However, since the occurrence of an OSF region is permitted at the outer periphery of the silicon crystal 10, compared to the situation with Manufacturing Method 1, the solid-liquid interface is convex slightly downward as shown in FIG. 10, and the pulling rate V is lower than in Manufacturing Method 1 as shown in FIG. 12. Accordingly, the further decrease in the pulling rate V results in an even better effect in terms of reducing the void defect size. Even though the rate is low, it is still on about the same level as the lower limit pulling rate at which no OSFs occurred under ordinary pulling conditions (0.76 mm/min), so there is no decrease in productivity.

With this manufacturing method, since V/G₁ is lowered to near the critical value, a low V/G₁ effect is obtained and the void defect size and density can be reduced. Furthermore, since V can be kept high, at the same level as under ordinary conditions, V·G₂ is larger, and the high V·G₂ effect allows the defect size to be further decreased (see FIG. 3). This means that the void defect size and density of the silicon wafer 100C can be reduced to the level indicated by the hatching in FIG. 5 in the region of the wafer plane from the center of the plane up to 10 mm to the inside of the outer periphery.

The fact that the lateral width of the silicon wafer 100C shown in FIG. 2 is narrower than the lateral width of the silicon wafers 100A and 100B obtained under ordinary conditions indicates that V/G₁ has become uniform within the wafer plane, and the void defect size and density have been uniformly decreased within the wafer plane.

With this manufacturing method, the silicon wafer 100C is heat treated along with controlling the oxygen concentration in the silicon crystal 10 so that OSF nuclei will not materialize into OSFs. More specifically, one of the following steps or a suitable combination of these steps is performed.

Step 1: The oxygen concentration in the silicon crystal 10 is controlled to 12.5×10¹⁷ atoms/cm³ or less.

Step 2: The silicon wafer 100C is heat treated at 1000° C. or higher.

Step 3: The silicon wafer 100C is heat treated in a non-oxidative atmosphere at 1000° C. or higher.

The effect of step 3 is that void defects are eradicated from the silicon wafer surface layer.

Naturally, steps 1, 2, and 3 may be added as needed to Manufacturing Method 1 or 2 of the first embodiment. Steps 1, 2, and 3 may be omitted with Manufacturing Method 3 of the second embodiment.

The working examples given above can be applied not only to when a polished wafer is being manufactured, but also to when an annealed wafer is being manufactured.

### Third Embodiment

We will now describe an embodiment in which it is possible to expand the allowable range of the growth condition V/G at which a defect-free crystal can be obtained.

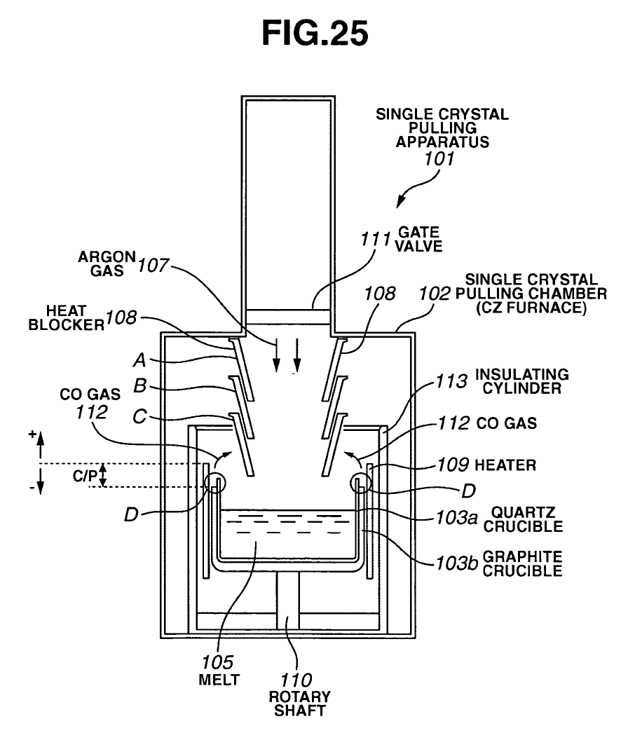

FIG. 25 is a side view of the apparatus constitution in this embodiment.

As shown in FIG. 25, the single crystal pulling apparatus 101 of this embodiment is equipped with a CZ furnace 102 as a chamber for pulling a single crystal.

A crucible 103a, in which the raw material polycrystalline silicon is melted and held as a melt 105, is provided inside the CZ furnace 102. The outside of the quartz crucible 103a is covered by a graphite crucible 103b. A main heater 109 for heating and melting the polycrystalline silicon raw material in the quartz crucible 103a is provided to the side on the outside of the quartz crucible 103b.

An insulating cylinder 113 is provided between the main heater 109 and the inner walls of the CZ furnace 102. A pulling mechanism (not shown) is provided above the quartz crucible 103a. A seed crystal is immersed in the melt 105 by this pulling mechanism, and an ingot of a silicon crystal is pulled up from the melt 105.

A gate valve 111 is attached above the CZ furnace 102. Closing the gate valve 111 allows the inside of the furnace 102 to be isolated from the outside atmosphere and to be kept under a vacuum (of about 20 Torr, for example).

Various kinds of evaporated material are generated within the CZ furnace 102 during the process of pulling a single crystal (one batch). Because of this, argon gas 107 is supplied as a carrier gas to the CZ furnace 102 from above, and is exhausted by pump from an exhaust port (not shown) below. This puts the inside of the furnace 102 under a specific reduced pressure, exhausts any impurities in the furnace 102 along with the argon gas 107, and keeps the inside of the furnace 102 clean. The supply flux of the argon gas 107 is set for each step in one batch.

Since there is a limit to the capacity of the quartz crucible 103a, additional polycrystalline silicon raw material is supplied by purge charging or recharging into the quartz crucible 103a according to the weight of the silicon crystal being pulled or according to the pulling rotational speed. Supplying additional polycrystalline silicon raw material into the quartz crucible 103a increases the amount of silicon single crystal manufactured per quartz crucible and reduces the manufacturing cost.

A rotary shaft 110 is fixed at the bottom of the graphite crucible 103b. As the silicon single crystal is being pulled, the quartz crucible 103a is rotated at a specific speed by the rotary shaft 110 along with the graphite crucible 103b.

The rotary shaft 110 can be raised and lowered vertically, allowing the quartz crucible 103a to be moved up and down to the desired position along with the graphite crucible 103b. The relative distance of the upper end of the graphite crucible 103b from the upper end of the heater 109 here is defined as the crucible position C/P. The polarity of the crucible position C/P is positive when the upper end of the graphite crucible 103b is located above the upper end of the heater 109, and is negative when the upper end of the graphite crucible 103b is located below the upper end of the heater 109.

A heat shield 108 (gas flow straightening cylinder) substantially in the form of an inverted truncated cone is provided around the pulled silicon crystal 10 and above the quartz crucible 103a. The heat shield 108 is provided in order to thermally insulate and shield the silicon single crystal being grown from the seed crystal from the radiant heat generated by high-temperature components such as the quartz crucible 103a, the graphite crucible 103b, the melt 105, and the heater 109. The heat shield 108 also prevents the growth of the single crystal from being hindered by the adhesion of impurities (such as amorphous silicon) generated within the furnace to the silicon single crystal being pulled. The size of the gap H between the lower end of the heat shield 108 and the surface of the melt 105 is an important parameter in terms of controlling the growth condition V/G of a silicon single crystal (V: growth rate, G: axial temperature gradient of the crystal). In view of this, an elevator mechanism for raising and lowering the heat shield 108 is provided in order to adjust the size of the gap H. This elevator mechanism allows the heat shield 108 to be raised and lowered vertically within the CZ furnace 102, allowing the heat shield 108 to be moved up and down to the desired position.

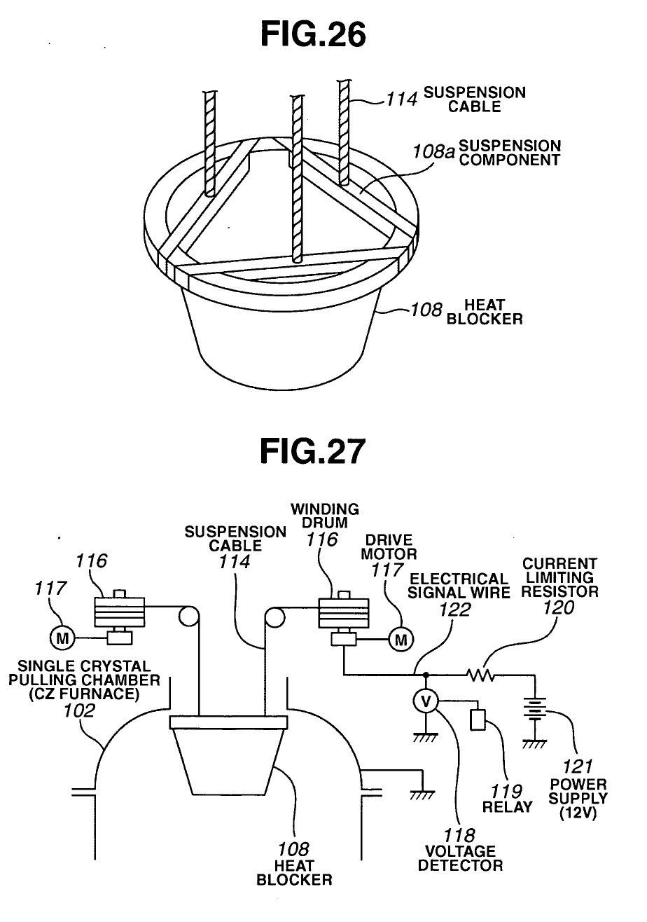

FIG. 26 is an oblique view of the heat shield 108. As shown in FIG. 26, a suspension component 108a is provided to the heat shield 108 as a frame that serves to make the upper surface flat. This suspension component 108a consists of a CCM (carbon-carbon fiber composite material), for example.

Suspension cables 114 are connected to the suspension component 108a, and the heat shield 108 is suspended from the suspension cables 114. The suspension cables 114 are made of tungsten, for example.

FIG. 27 illustrates the elevator mechanism for raising and lowering the heat shield 108.

As shown in FIG. 27, the suspension cables 114 are wound around winding drums 116. The winding drums 116 are rotated by actuating a drive motors 117. The drive motors 117 are actuated by voltage (such as 12V) applied from a DC power source 121 through electrical signal wiring 122. A current limiting resistor 120 is interposed along the electrical signal wiring 122 between the power source 121 and the drive motors 117, and limits the current flowing to the drive motors 117.

The heat shield 108, the suspension cables 114, and the winding drums 116 are electrically connected to the electrical signal wiring 122. A voltage detector 118 is provided for detecting the voltage applied to the electrical signal wiring 122. A relay 119 is provided to the voltage detector 118, and this relay 119 is energized and halts the drive motors 117 when the voltage detected by the voltage detector 118 reaches a specific value (such as 6V). The CZ furnace 102 is grounded.

As shown in FIG. 25, the heat shield 108 is formed in an outside diameter corresponding to the size of the top opening in the insulating cylinder 113. A is the position when the heat shield 108 is raised until its edge comes into contact with the inner walls of the CZ furnace 102, B is the position when the heat shield 108 is lowered below position A and the lower part of the heat shield 108 is located at the opening of the insulating cylinder 113, and C is the position when the heat shield 108 is further lowered past position B and the upper part of the heat shield 108 is located at the opening of the insulating cylinder 113.

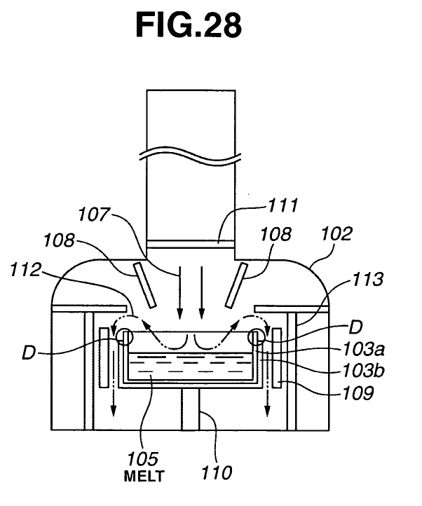

As shown in FIG. 28, the heat shield 108 guides the argon gas 107 supplied from above into the CZ furnace 102 to the center of the surface of the melt 105, and guides this gas through the surface of the melt 105 to the peripheral edge of the surface of the melt 105. The argon gas 107 picks up the CO gas 112 generated inside the CZ furnace 102, and particularly the CO gas 112 that drifts to the top of the CZ furnace 102, and the CO gas 112 generated at the portion D where the quartz crucible 103a and the graphite crucible 103b touch at the upper end, and is exhausted from an exhaust port provided to the lower part of the CZ furnace 102.

The heat shield 108 also stabilizes the rate of gas flow over the surface of the melt 105, allowing the oxygen generated from the melt 105 to be kept in a stable state.

The operation of the apparatus in this embodiment will now be described.

In short, the process involved in the CZ method consists of the steps of melting, melt stabilization, pulling, cooling, and withdrawal. With a method involving recharging, this process is repeated so that a plurality of silicon single crystals are pulled up, and every time one silicon single crystal is pulled up, additional polycrystalline silicon raw material is supplied in the next melting step. With a method involving purge charging, the initial polycrystalline silicon raw material is supplied in the melting step, and additional raw material is supplied after the initial portion has melted. The gate valve 111 is closed during recharging or purge charging. The course of manufacturing a silicon single crystal, the CO gas 112 is readily incorporated into the melt 105, especially in the melting step, and it is the that the CO gas 112 is particularly apt to be incorporated into the melt 105 during that portion of the melting step while the gate valve 111 is closed.

Melting Step

The gate valve 111 is closed in the melting step. With the gate valve 111 closed, the heat shield 108 is raised to position A shown in FIG. 25.

Specifically, the winding drums 116 are rotated by actuating the drive motors 117 with the elevator mechanism shown in FIG. 27. This raises the suspension cables 114 and in turn raises the heat shield 108. Once the heat shield 108 reaches position A, the upper end of the heat shield 108 comes into contact with the inner walls of the CZ furnace 102. This grounds the heat shield 108, so that the electrical signal wiring 122 has ground potential through the heat shield 108, the suspension cables 114, and the winding drums 116. Accordingly, the voltage detected by the voltage detector 118 drops under the threshold value, the relay 119 is energized, and the drive motors 117 are halted. As a result, the heat shield 108 stops exactly at position A where it is touching the inner walls of the CZ furnace 102.

Since the suspension component 108a of the heat shield 108 is made of a flexible CCM, it can absorb any bending of the suspension cables 114 should the drive motors 117 over-run.

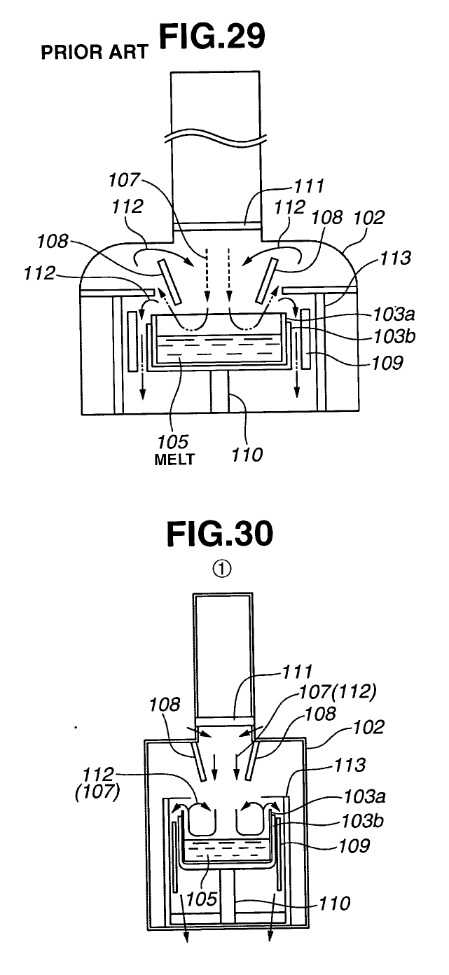

FIG. 28 shows the flow of gas when the heat shield 108 is located at position A. In the past, the heat shield 108 would have been located at position B as shown in FIG. 29. The flow of gas in FIG. 28 will be contrast with that in FIG. 29.

As shown in FIG. 29, usually, in the melting step, the crucible position C/P is kept higher than the position in the pulling step in order to absorb heat from the heater 109 and to suppress entrainment of the CO gas 112. Meanwhile, from the standpoint of improving thermal efficiency in the melting of the polycrystalline silicon raw material, the heat shield 108 must be located at as low a position as possible (C position), but an attempt is made to locate the heat shield 108 at an intermediate position B in order to avoid contact with the raw material or the melt 105. In this state, part of the argon gas 107 is exhausted from above the CZ furnace 102 to below the heat shield 108 and through the gap between the heater 109 and the graphite crucible 103b to below the CZ furnace 102, along with the CO gas 112 produced inside the CZ furnace 102, but part of the argon gas 107 flows along with the CO gas 112 from the outside of the heat shield 108 toward the melt 105 via the upper end and inside of the heat shield 108; that is, the gas forms a flow that spirals vertically around the heat shield 108. Accordingly, the CO gas 112 comes into contact with the melt 105, and carbon tends to be incorporated into the melt 105.

In contrast, as shown in FIG. 28, when the heat shield 108 is located at position A where its upper end comes into contact with the inner walls of the CZ furnace 102, the argon gas 107 flows along with the CO gas 112 from the outside of the heat shield 108 toward the melt 105 via the upper end and inside of the heat shield 108; that is, the gas does not form a flow that spirals vertically around the heat shield 108. Specifically, the flow of the argon gas 107 is straightened, picks up the CO gas 112 produced inside the CZ furnace 102, and is efficiently exhausted from above the CZ furnace 102 to below the heat shield 108 and to below the CZ furnace 102 via the gap between the heater 109 and the graphite crucible 103b. The effect of thus straightening the flow of the argon gas 107 is that not only the CO gas 112 that drifts to the upper part of the CZ furnace 102, but also the CO gas 112 generated by reaction between the quartz crucible 103a and the graphite crucible 103b are efficiently exhausted downward, so the amount of carbon incorporated into the melt 105 is markedly lower than in the case of FIG. 29.

This makes it possible to reduce the carbon concentration in a pulled silicon single crystal to 3×10¹⁵ atoms/cm³ or less.

Further, since the argon gas 107 is efficiently exhausted as a result of the flow straightening of the gas, impurities such as amorphous silicon in the CZ furnace 102 are also efficiently exhausted, which provides the side benefit that furnace contamination can be reduced over that in the past.

Also, in this embodiment, since the heat shield 108 is located at position A where it touches the inner walls of the CZ furnace 102, swaying of the heat shield 108 as a result of gas flow is suppressed, and a more stable gas flow is formed.

Pulling Step

A seed crystal is immersed in the melt 105 in the pulling step, and an ingot of a silicon crystal is generated by pulling up the seed crystal. In the pulling step, the heat shield 108 is located at a position where it can perform its intended function, that is, at a position where the pulled silicon single crystal can be shielded from the radiant heat generated by the melt 105 in the quartz crucible 103a. If the heat shield 108 has been located at the A position in the melting step, it is lowered to the B position.

In the pulling step, the silicon single crystal is pulled while the growth condition V/G (V: growth rate, G: axial temperature gradient of the crystal) is adjusted such that void defects, OSFs (oxidation induced stacking faults), and dislocation clusters (interstitial silicon dislocation defects) are eliminated from the pulled silicon single crystal.

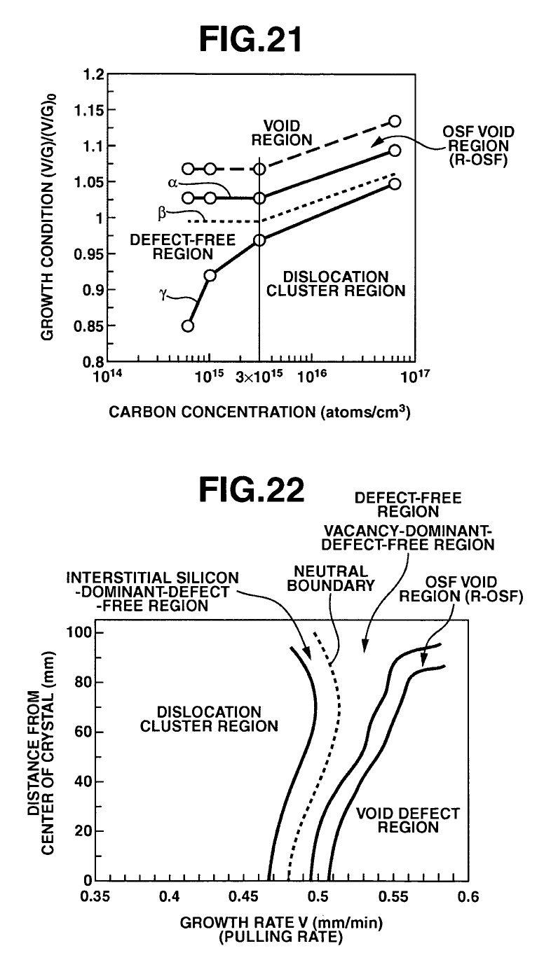

FIG. 21 is described in detail below, but the relationship between the carbon concentration in the silicon single crystal and the growth condition V/G during pulling will be described here through reference to FIG. 21. The horizontal axis in FIG. 21 is the carbon concentration in a silicon single crystal (atoms/cm³), while the vertical axis is the growth condition V/G, standardized at (V/G)₀. (V/G)₀ here is the critical value of V/G in a crystal to which no carbon has been added, that is, the V/G value expressing a neutral state under a condition of a trace carbon amount.

As shown in FIG. 21, if the carbon concentration in the silicon single crystal is 3×10¹⁵ atoms/cm³ or less, there is a sharp expansion in the range over which defect-free crystals can be manufactured (defect-free region). This expands the allowable range of the growth condition V/G along the vertical axis in which defect-free crystals can be obtained. Accordingly, even though V/G varies dynamically during crystal growth, the allowable range of the pulling rate V is large and the growth condition V/G is easy to control.

Therefore, defect-free silicon single crystals can be acquired at a higher rate, and the cost of manufacturing a defect-free silicon single crystal is decreased. As a result, it is possible to manufacture a defect-free crystal stably in an industrial setting. For example, a silicon wafer that will make an excellent IC or LSI chip substrate can be manufactured at a high yield, and a silicon wafer for a particle monitor, which is indispensable in the manufacture of ICs and LSI chips, can be manufactured inexpensively.

Also, with this embodiment, a flow of argon gas 107 with which the CO gas 112 is not incorporated into the melt 105 can be stably formed, and the CO gas 112 can be efficiently exhausted to outside the furnace, merely by utilizing and positioning the existing heat shield 108 in a single crystal pulling apparatus 101. Accordingly, compared to Prior Art 9 to 12, the cost of manufacturing the single crystal pulling apparatus 101 itself can be lowered, and the carbon concentration in the silicon single crystal can be stably lowered.

In the above description, the heat shield 108 is raised to position A where it touches the inner walls of the CZ furnace 102, but the heat shield 108 does not necessarily have to be in complete contact with the inner walls, and as long as the same gas flow as shown in FIG. 28 can be achieved, the upper end of the heat shield 108 may be in a state in which it is close to the inner walls of the CZ furnace 102 (about 0 to 30 mm away).

Also, in the above description, the crucible position C/P was the same as the position in an ordinary (conventional) melting step (the same position as in FIG. 29), but the rotary shaft 110 may be lowered so as to lower the crucible position C/P to a position lower than that in an ordinary (conventional) melting step, and further decrease the carbon concentration in the silicon single crystal.

Also, in the above description, no mention was made of the flux of the argon gas 107, but the carbon concentration in the silicon single crystal may be further lowered by increasing the flux of the argon gas 107 over the flux set in an ordinary (conventional) melting step.

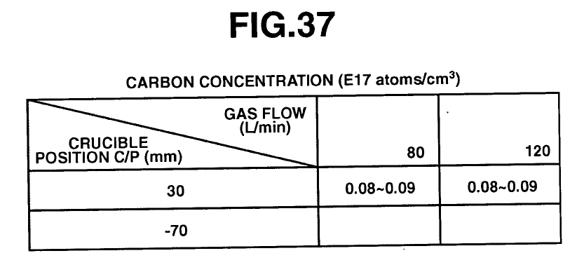

FIG. 37 is a table of the carbon concentration (atoms/cm³) in a silicon single crystal when the crucible position C/P (mm) and the flux of the argon gas 107 (L/min) were varied in a condition where a heat shield is positioned at the position A. As shown in FIG. 37, it was confirmed that a reduction in carbon concentration is achieved by either setting the crucible position C/P to a negative position or increasing the gas flux. It can be seen that the greatest reduction in carbon concentration was when the crucible position C/P was lowered to −70 mm and the flux of the argon gas 107 was increased to 120 L/min, at which the carbon concentration was 0.01×10¹⁷ atoms/cm³.

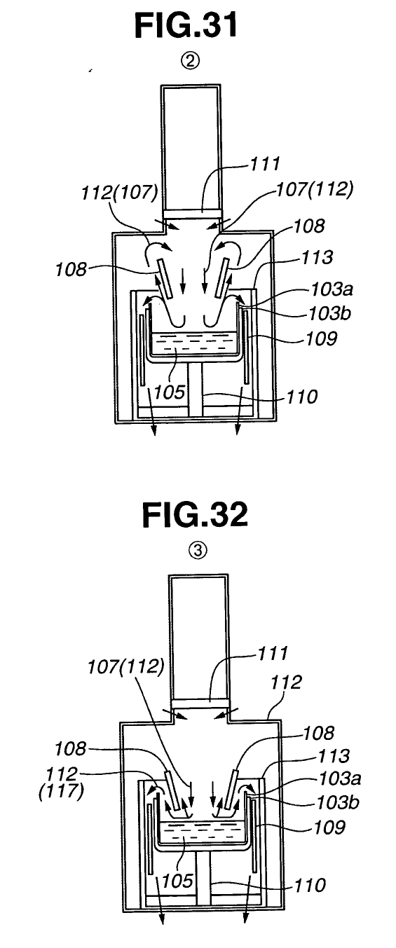

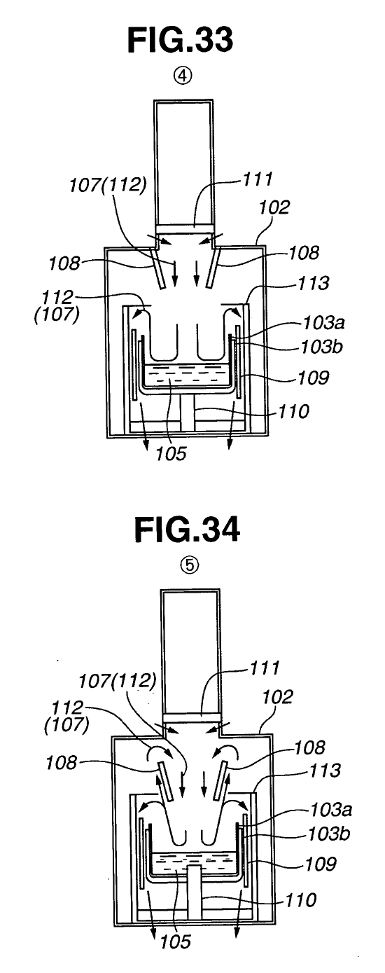

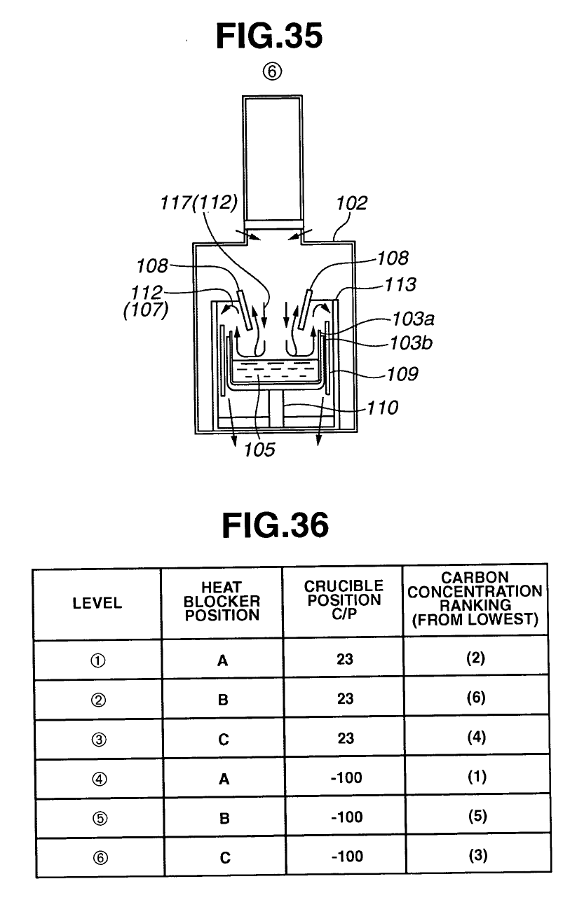

The relationship between the position of the heat shield 108, the crucible position C/P, the flow of gas, and the carbon concentration will now be described through reference to FIGS. 30 to 35. FIG. 36 is a table of the position of the heat shield 108, the crucible position C/P, and the carbon concentration ranking (from 1 to 6 in ascending order), correlated to the levels \textcircled{1} to \textcircled{6} in FIGS. 30 to 35. As shown in FIG. 36, the carbon concentration in the silicon single crystal rose in the order of level \textcircled{4} in FIG. 33→level \textcircled{1} in FIG. 30→level \textcircled{6} in FIG. 35→level \textcircled{3} in FIG. 32→level \textcircled{5} in FIG. 34→level \textcircled{2} in FIG. 31. The relationship between carbon concentration and gas flow in ascending order of carbon concentration will not be described.

FIG. 33 is a diagram of the flow of gas at level \textcircled{4}, where the heat shield 108 was located at position A and the crucible position C/P was positioned at −100 mm. As shown in FIG. 33, at level \textcircled{4}, the argon gas 107 flows along with the CO gas 112 from the outside of the heat shield 108, through the upper end and inside of the heat shield 108, toward the melt 105; that is, no flow is formed that spirals vertically around the heat shield 108. Specifically, the flow of the argon gas 107 is straightened. The flow of gas is more stratified at level \textcircled{4} of FIG. 33 than at any other level, and no eddy that would draw the gas inward is formed within the quartz crucible 103a. Accordingly, the carbon concentration is lower at level \textcircled{4} than at any other level (carbon concentration ranking (1)).

FIG. 30 is a diagram of the flow of gas at level \textcircled{1}, where the heat shield 108 was located at position A and the crucible position C/P was positioned at 23 mm. As shown in FIG. 30, at level \textcircled{1}, the argon gas 107 flows along with the CO gas 112 from the outside of the heat shield 108, through the upper end and inside of the heat shield 108, toward the melt 105; that is, no flow is formed that spirals vertically around the heat shield 108. Specifically, the flow of the argon gas 107 is straightened. However, compared to level \textcircled{4} in FIG. 33, at level \textcircled{1} in FIG. 30 an eddy that draws the gas inward is formed within the quartz crucible 103a. Accordingly, the reduction in the carbon concentration is less than at level \textcircled{4} in FIG. 33 (carbon concentration ranking (2)).

FIG. 35 is a diagram of the flow of gas at level \textcircled{6}, where the heat shield 108 was located at position C and the crucible position C/P was positioned at −100 mm. Similarly, FIG. 32 shows the flow of gas at level \textcircled{3}, where the heat shield 108 was located at position C and the crucible position C/P was positioned at 23 mm.

As shown in FIGS. 35 and 32, at levels \textcircled{6} and \textcircled{3}, the argon gas 107 flows along with the CO gas 112 from the outside of the heat shield 108, through the upper end and inside of the heat shield 108, toward the melt 105; that is, no flow is formed that spirals vertically around the heat shield 108. Specifically, the flow of the argon gas 107 is straightened. The flow of gas here can be considered to be stratified, but is such that gas rises up from above the melt 105, goes through the inside of the heat shield 108, and flows back above the heat shield 108, so the reduction in the carbon concentration is less than at levels \textcircled{4} and \textcircled{1} (carbon concentration ranking (3) at level \textcircled{6}, and carbon concentration ranking (4) at level (3). Furthermore, when the heat shield 108 is located at the C position, thee is the danger that the upper part of the heat shield 108 will touch the insulating cylinder 113 and its opening, generating carbon. It is therefore also undesirable for the heat shield 108 to be located at the C position in terms of reducing sources of carbon generation.

FIG. 34 is a diagram of the flow of gas at level \textcircled{5}, where the heat shield 108 was located at position B and the crucible position C/P was positioned at −100 mm. Similarly, FIG. 31 shows the flow of gas at level \textcircled{2}, where the heat shield 108 was located at position B and the crucible position C/P was positioned at 23 mm.

As shown in FIGS. 34 and 31, at levels \textcircled{5} and \textcircled{2}, the argon gas 107 flows along with the CO gas 112 from the outside of the heat shield 108, through the upper end and inside of the heat shield 108, toward the melt 105; that is, a flow is formed that spirals vertically around the heat shield 108. Specifically, the flow of the argon gas 107 is not straightened. Consequently, the CO gas 112 is readily incorporated into the melt 105 and the carbon concentration rises (carbon concentration ranking (5) at level \textcircled{5}, and carbon concentration ranking (6) at level \textcircled{2}).

When the flux of the argon gas 107 was increased from 80 to 100 L/min at each of the levels \textcircled{1} to \textcircled{6}, the carbon concentration was lower at each level when the flux was thus increased.

The above revealed that parameters that affect the carbon concentration in a silicon single crystal include the position of the heat shield 108, the crucible position C/P, and the flux of the argon gas 107, and that as shown in FIG. 33 (level \textcircled{4}), the carbon concentration can be lowered most by locating the heat shield 108 at the position A where it touches the inner walls of the CZ furnace 102 or at a position close to the inner walls of the CZ furnace 102, setting the crucible position C/P to a negative position, that is such that the upper end of the graphite crucible 103b is located below the upper end of the heater 109, and increasing the flux of the argon gas 107. The most important parameter, however, is the position of the heat shield 108, and as shown in FIG. 33 (level \textcircled{4}) and FIG. 30 (level \textcircled{1}), the carbon concentration can be lowered by locating the heat shield 108 either at the position A where it touches the inner walls of the CZ furnace 102 or at a position close to the inner walls of the CZ furnace 102, regardless of the crucible position C/P.

In the above description, we assumed a case in which the heat shield 108 and the crucibles 103a and 103b were located at the positions indicated in FIG. 28 or FIG. 33 (level \textcircled{4}) or FIG. 30 (level \textcircled{1}) when the gate valve 111 was closed during the melting step, but the heat shield 108 and the crucibles 103a and 103b may also be located at the positions shown in FIG. 28 or FIG. 33 (level \textcircled{4}) or FIG. 30 (level \textcircled{1}) when the gate valve 111 was not closed during the melting step. Furthermore, the same positioning may be performed in a step other than the melting step.

The means and method for lowering the carbon concentration in the silicon single crystal may be the above-mentioned Prior Art 9 to 12. For instance, the graphite members exposed to high temperature, such as the graphite crucible 103b, the heater 109, or the heat shield 108, may be covered with SiC so as to suppress the very generation of the CO gas 112.

Next, the relationship between the growth condition V/G and the carbon concentration in the silicon single crystal will be discussed through reference to FIGS. 21 to 24.

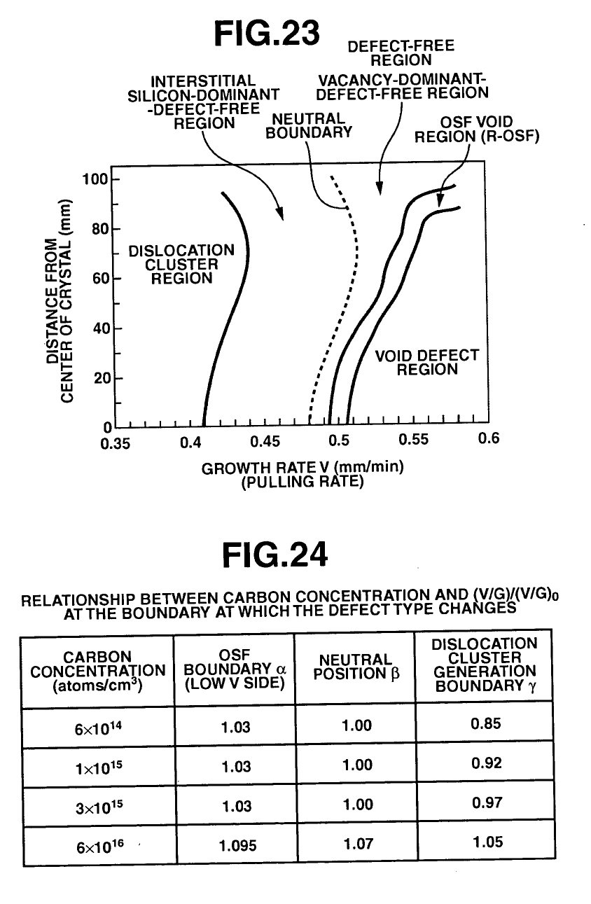

FIG. 22 shows the distribution of defect types in the crystal when the growth rate V was varied, and shows the results of an experiment in which a silicon single crystal with a diameter of 200 mm and a carbon concentration of 3×10¹⁵ atoms/cm³ was pulled up using the single crystal pulling apparatus 101, in which the quartz crucible 103a had a diameter of 22 inches. In this experiment a silicon single crystal was obtained by gradually decreasing the growth rate V. FIG. 23 shows the distribution of defect types in the crystal under the same conditions as in FIG. 22, except that the carbon concentration was lowered further than in FIG. 22 (to 6×10¹⁴ atoms/cm³).

The horizontal axis in FIGS. 22 and 23 is the growth rate V (mm/min), and the vertical axis is the distance from the center of the crystal (radial position) (mm).

In this experiment, the distribution of defect types at various locations in the crystal was determined and evaluated by a combination of X-ray topography after oxygen precipitation heat treatment, X-ray topography after copper decoloration, and Secco etching. The carbon concentration (3×10¹⁵ atoms/cm³) of the silicon single crystal in FIG. 22 was measured by FTIR method using a sample with a thickness of 2 mm. The carbon concentration (6×10¹⁴ atoms/cm³) of the silicon single crystal in FIG. 23 was measured by radioactivation analysis.

As shown in FIGS. 22 and 23, the various defect types appear correlated to the horizontal axis position and the vertical axis position. These are a void defect region where void defects appear, an OSF ring region where R-OSFs (OSF rings) appear, and a dislocation cluster region where dislocation clusters appear. The defect-free region where defect-free crystals are obtained appears between the dislocation cluster region and the void defect region. The defect-free region is divided into a vacancy-dominant-defect-free region and interstitial silicon-dominant-defect-free region, and the neutral line between these is indicated by the broken line.

A comparison of FIG. 23 with FIG. 22 reveals that in FIG. 23, in which the carbon concentration is lower than in FIG. 22, and the carbon concentration is ultra-low (6×10¹⁴ atoms/cm³), the range of the growth rate V corresponding to the defect-free region is markedly expanded. In FIG. 22, there is no growth rate V at which the crystal will be defect-free over the entire region in the radial direction of the crystal, and at a constant growth rate V, some kind of defect is always present somewhere in the radial direction of the crystal. In FIG. 23, though, the range of growth rate V corresponding to a defect-free region is markedly expanded by the extremely low carbon concentration, and the crystal is defect-free over the entire region in the radial direction of the crystal even when the growth rate V is varied somewhat.

To examine the relationship between carbon concentration and defect type, we grew silicon single crystals with a carbon concentration of 6×10¹⁴ atoms/cm³, 1×10¹⁵ atoms/cm³, 3×10¹⁵ atoms/cm³, and 6×10¹⁶ atoms/cm³, and evaluated these crystals in the same manner as in the experiments shown in FIGS. 22 and 23. The silicon single crystal with a high carbon concentration of 6×10¹⁶ atoms/cm³ here was acquired by intentionally doping with carbon, while the silicon single crystals with a low carbon concentration of 6×10¹⁴ atoms/cm³ and 1×10¹⁵ atoms/cm³ were acquired by efficiently exhausting the CO gas 112 with the apparatus 101 of the embodiment shown in FIG. 25.

The table in FIG. 24 shows the experiment results, and shows the (V/G)/(V/G)₀ value at the boundary at which the defect type changes, correlated to carbon concentration. FIG. 24 gives the OSF boundary α on the low growth rate V side, the neutral position β, and the (V/G)/(V/G)₀ at the dislocation cluster generation boundary γ. The OSF boundary α on the low growth rate V side refers to the boundary between the OSF ring region and the defect-free region; the neutral position β refers to the boundary in the defect-free region that divides the vacancy-dominant-defect-free region from the interstitial silicon-dominant-defect-free region; and the dislocation cluster generation boundary γ refers to the boundary between the defect-free region and the dislocation cluster region.

(V/G)/(V/G)₀, as discussed above, is the growth condition V/G standardized at a critical value (V/G)₀, and (V/G)₀ is the V/G value expressing a neutral state under a condition of a trace carbon concentration. G was calculated using the method disclosed in Patent Document 3 (pertaining to the inventors of the present invention).

FIG. 21 shows the experiment results given in the table of FIG. 24, as the distribution of defect types correlated to the carbon concentration (atoms/cm³) and the standardized growth condition (V/G)/(V/G)₀. As discussed above, once the carbon concentration in the silicon single crystal drops to 3×10¹⁵ atoms/cm³ or lower, there is a sharp expansion in the range of the growth condition V/G at which a defect-free silicon single crystal can be obtained.

In the above description, the carbon concentration was lowered to 3×10¹⁵ atoms/cm³ or lower by efficiently exhausting the CO gas 112 using the pulling apparatus 101 shown in FIG. 25, but this technique need not be employed, and the carbon concentration may instead be lowered by applying just the prior art given in Prior Art 9 to 12.

1. A method for manufacturing a silicon wafer, in which a silicon crystal is pulled from a silicon melt, and a silicon wafer is acquired from the pulled silicon crystal,
wherein the silicon crystal is pulled up by lowering a growth condition V/G₁ (V: growth rate, G₁: axial temperature gradient near a melting point of the silicon crystal) to near a critical value in a state in which the axial temperature gradient G₁ near the melting point of the silicon crystal is increased and a solid-liquid interface, which is a boundary between the silicon crystal and the melt during the pulling of the silicon crystal, is convex with respect to the melt surface.

2. The method for manufacturing a silicon wafer according to claim 1, wherein a cooler is used to cool the silicon crystal, thereby lowering the growth condition V/G₁ to near the critical value in a state in which the solid-liquid interface is convex with respect to the melt surface within a range in which the growth rate V is from 75 to 97% of Vmax (the limit growth rate at which growth is possible without deformation of the silicon crystal), and the silicon crystal is pulled in which no OSF (oxidation induced stacking fault) region is present anywhere in the plane of the silicon wafer.

3. The method for manufacturing a silicon wafer according to claim 1, wherein a cooler is used to cool the silicon crystal, thereby lowering the growth condition V/G₁ to near the critical value in the state in which the axial temperature gradient G₁ near the melting point of the silicon crystal is increased.

4. The method for manufacturing a silicon wafer according to claim 1, wherein a magnetic field is applied to the silicon melt to make the solid-liquid interface convex with respect to the melt surface.

5. The method for manufacturing a silicon wafer according to claim 1, wherein a cooler is used to cool the silicon crystal, and a rotational speed of the silicon crystal, or a rotational speed of the crucible containing the silicon melt, is adjusted, thereby making the solid-liquid interface convex with respect to the melt surface.

6. A method for manufacturing a silicon wafer, in which a silicon crystal is pulled from a silicon melt, and a silicon wafer is acquired from the pulled silicon crystal,
wherein a cooler is used to cool the silicon crystal, thereby lowering a growth condition V/G₁ to near a critical value in a state in which the axial temperature gradient G₁ near a melting point of the silicon crystal has been increased, and
the silicon crystal is pulled in which no OSF (oxidation induced stacking fault) region is present in a plane of the silicon wafer at least from a center of the plane up to 10 mm from an outer periphery.

7. The method for manufacturing a silicon wafer according to claim 6, wherein an oxygen concentration in the silicon crystal is controlled to be not more than 12.5×10¹⁷ atoms/cm³ (Year 1979 ASTM).

8. The method for manufacturing a silicon wafer according to claim 6, wherein the silicon wafer is subjected to heat treatment at 1000° C. or higher so that OSF nuclei will not materialize as OSFs in the silicon wafer.

9. The method for manufacturing a silicon wafer according to claim 6, wherein the silicon wafer is subjected to heat treatment at 1000° C. or higher in a non-oxidative atmosphere so that OSF nuclei will not materialize as OSFs in the silicon wafer and so that void defects will be eliminated in the silicon wafer surface layer.

10. An apparatus for manufacturing a silicon wafer, with which a silicon crystal is pulled from a silicon melt by a pulling mechanism, and the silicon wafer is acquired from the pulled silicon crystal,
wherein a cooler for cooling the silicon crystal is provided above the silicon melt, and
a silicon crystal pulling rate by the pulling mechanism and an amount of cooling by the cooler are adjusted,
thereby lowering a growth condition V/G₁ (V: growth rate, G₁: axial temperature gradient near a melting point of the silicon crystal) to near a critical value in a state in which the axial temperature gradient G₁ near the melting point of the silicon crystal is increased and a solid-liquid interface, which is a boundary between the silicon crystal and the melt during the pulling of the silicon crystal, is convex with respect to a melt surface,
and the silicon crystal is pulled up.

11. The apparatus for manufacturing a silicon wafer according to claim 10, wherein the cooler is used to cool the silicon crystal, thereby lowering the growth condition V/G₁ to near the critical value in the state in which the solid-liquid interface is convex with respect to the melt surface within a range in which the growth rate V is from 75 to 97% of Vmax (a limit growth rate at which growth is possible without deformation of the silicon crystal),
and the silicon crystal is pulled in which no OSF (oxidation induced stacking fault) region is present anywhere in a plane of the silicon wafer.

12. An apparatus for manufacturing a silicon wafer, in which a silicon crystal is pulled from a silicon melt, and the silicon wafer is acquired from the pulled silicon crystal,
wherein a cooler for cooling the silicon crystal is provided above the silicon melt, and
a silicon crystal pulling rate by the pulling mechanism and an amount of cooling by the cooler are adjusted,
thereby lowering a growth condition V/G₁ to near a critical value in a state in which an axial temperature gradient G₁ near a melting point of the silicon crystal has been increased, and
the silicon crystal is pulled in which no OSF (oxidation induced stacking fault) region is present in a plane of the silicon wafer at least from a center of the plane up to 10 mm from an outer periphery.

13. The apparatus for manufacturing a silicon wafer according to claim 10, wherein the cooler is disposed so as to surround the silicon crystal at a distance of 30 to 500 mm from the silicon melt.

14. The apparatus for manufacturing a silicon wafer according to claim 12, wherein the cooler is disposed so as to surround the silicon crystal at a distance of 30 to 500 mm from the silicon melt.

15. The apparatus for manufacturing a silicon wafer according to claim 10, wherein a heat shield is provided above the silicon melt, and a gap between a lower end of the heat shield and the silicon melt surface is set to between 20 and 100 mm.

16. The apparatus for manufacturing a silicon wafer according to claim 12, wherein a heat shield is provided above the silicon melt, and a gap between a lower end of the heat shield and the silicon melt surface is set to between 20 and 100 mm.

17. A silicon wafer, acquired by pulling from a silicon melt,
wherein no OSF (oxidation induced stacking fault) region is present anywhere in a plane of the silicon wafer, an average void defect density over the entire plane of the silicon wafer is not more than 5×10⁶/cm³, and an average void defect size over the entire plane of the silicon wafer is not more than 100 nm.

18. A silicon wafer, acquired by pulling from a silicon melt,
wherein no OSF (oxidation induced stacking fault) region is present in a plane of the silicon wafer at least from a center of the plane up to 10 mm from an outer periphery, an average void defect density in the plane of the silicon wafer at least from a center of the plane up to 10 mm from an outer periphery is not more than 5×10⁶/cm³, and an average void defect size is not more than 100 nm.

19. A method for manufacturing a defect-free silicon single crystal in which void defects, OSFs (oxidation induced stacking faults), and dislocation clusters (interstitial silicon dislocation defects) have been eliminated by setting a carbon concentration to less than 1×10¹⁵ atoms/cm³ and adjusting a growth condition V/G (V: growth rate, G: axial temperature gradient of the crystal).

20. A defect-free silicon single crystal in which void defects, OSFs (oxidation induced stacking faults), and dislocation clusters (interstitial silicon dislocation defects) have been eliminated, manufactured by setting a carbon concentration to less than 1×10¹⁵ atoms/cm³ and adjusting a growth condition V/G (V: growth rate, G: axial temperature gradient of the crystal).

21. An apparatus for pulling a silicon single crystal, comprising: a single crystal pulling chamber in which a carrier gas is supplied from above and exhausted from below; a crucible that is provided inside the single crystal pulling chamber, and into which a raw material is supplied and melted; and a heat shield that is disposed above the crucible, for guiding the carrier gas to a melt surface inside the crucible, in which the silicon single crystal is pulled from the melt inside the crucible,
wherein the heat shield can be raised and lowered,
the heat shield is positioned where a carbon concentration inside the pulled silicon single crystal is 3×10¹⁵ atoms/cm³ or less, and
the silicon single crystal is pulled while a growth condition V/G (V: growth rate, G: axial temperature gradient of the crystal) is adjusted such that void defects, OSFs (oxidation induced stacking faults), and dislocation clusters (interstitial silicon dislocation defects) are eliminated from the pulled silicon single crystal.
